(19) United States
(12) Patent Application Publication
(10) Pub. No.: US 2026/0304891 A1
(43) Pub. Date: Oct. 1, 2026

(54) SEMICONDUCTOR DEVICES INCLUDING CENTRAL INSULATING LAYER

(71) Applicant: SAMSUNG ELECTRONICS CO., LTD., Suwon-si (KR)

(72) Inventors: Jeonghyeon Lee, Suwon-si (KR); Hyungkoo Kang, Suwon-si (KR); Jonghan Lee, Suwon-si (KR)

(73) Assignee: SAMSUNG ELECTRONICS CO., LTD., Suwon-si (KR)

(21) Appl. No.: 19/338,572

(22) Filed: Sep. 24, 2025

(30) Foreign Application Priority Data
Mar. 26, 2025 (KR) 10-2025-0038462

(51) Int. Cl. H10D 64/23; H01L 23/48; H10D 84/83

(52) U.S. Cl. CPC H10D 64/251; H10D 84/832; H10W 20/20

(57) ABSTRACT

A semiconductor device may include a substrate; an active pattern extending on the first surface of the substrate in a first direction and including at least one conductivity-type impurity region; a first conductivity-type epitaxial pattern on the at least one conductivity-type impurity region; a second conductivity-type epitaxial pattern on the at least one conductivity-type impurity region, and spaced apart from the first conductivity-type epitaxial pattern in the first direction; a first interlayer insulating layer on the first surface of the substrate and the first and second conductivity epitaxial patterns; a first intermediate insulating layer on the first interlayer insulating layer and including a first opening extending in a second direction, intersecting the first direction; and a central insulating layer between the first and second conductivity-type epitaxial patterns, and extending in the second direction and in the first opening.

### CROSS-REFERENCE TO RELATED APPLICATIONS

This application claims benefit of priority to Korean Patent Application No. 10-2025-0038462, filed on Mar. 26, 2025, in the Korean Intellectual Property Office, the disclosure of which is incorporated herein by reference in its entirety.

### BACKGROUND

### 1. Field

Example embodiments of the present disclosure relate to a semiconductor device including a central insulating layer.

### 2. Description of Background Art

As demand for high performance, high speed, and/or multifunctionality of a semiconductor device increases, integration density of semiconductor devices has been increased. To overcome limitations in operating properties due to reduction of a size of planar metal oxide semiconductor field-effect transistor (FET) (MOSFET), efforts have been made to develop a semiconductor device including a finFET including a fin-shaped channel and a gate-all-around field effect transistor including nanosheets surrounded by a gate.

### SUMMARY

According to some example embodiments of the present disclosure, a semiconductor device having improved electrical properties and reliability may be provided.

According to some example embodiments of the present disclosure, a semiconductor device may include: a substrate; an active pattern extending in a first direction on a first surface of the substrate, the active pattern including at least one conductivity-type impurity region; a first conductivity-type epitaxial pattern on the at least one conductivity-type impurity region; a second conductivity-type epitaxial pattern on the at least one conductivity-type impurity region, and spaced apart from the first conductivity-type epitaxial pattern in the first direction; a first interlayer insulating layer on the first surface of the substrate, the first conductivity-type epitaxial pattern, and the second conductivity-type epitaxial pattern; a first intermediate insulating layer on the first interlayer insulating layer, the first intermediate insulating layer including a first opening extending in a second direction, intersecting the first direction; a central insulating layer between the first conductivity-type epitaxial pattern and the second conductivity-type epitaxial pattern, wherein the central insulating layer extends in the second direction and is in the first opening; and contact structures penetrating through the first interlayer insulating layer and the first intermediate insulating layer, and respectively in contact with the first conductivity-type epitaxial pattern and the second conductivity-type epitaxial pattern.

According to some example embodiments of the present disclosure, a semiconductor device may include: a substrate; a first device on a first surface of the substrate; and a second device on the first surface of the substrate and spaced apart from the first device, wherein the first device includes: a first active pattern extending in a first direction on the first surface of the substrate; semiconductor patterns on the first active pattern, the semiconductor patterns spaced apart from each other in a third direction crossing the first surface of the substrate; a gate electrode extending in a second direction intersecting the first direction and the third direction, the gate electrode intersecting and at least partially surrounding the semiconductor patterns; source/drain patterns in contact with the semiconductor patterns on at least one side of the gate electrode; an isolation structure extending in the second direction, the isolation structure being between adjacent ones of the source/drain patterns; and source/drain contacts in contact with the source/drain patterns, wherein the second device includes: a second active pattern including a first conductivity-type impurity region and a second conductivity-type impurity region, the first conductivity-type impurity region and the second conductivity-type impurity region extending in the first direction on the first surface of the substrate, and contacting each other in the first direction; a first conductivity-type epitaxial pattern on the first conductivity-type impurity region; a second conductivity-type epitaxial pattern on the second conductivity-type impurity region, the second conductivity-type epitaxial pattern spaced apart from the first conductivity-type epitaxial pattern in the first direction; an interlayer insulating layer on the first surface of the substrate, the first conductivity-type epitaxial pattern, and the second conductivity-type epitaxial pattern; an intermediate insulating layer including an opening extending in the second direction, the intermediate insulating layer being on the interlayer insulating layer; and a central insulating layer between the first conductivity-type epitaxial pattern and the second conductivity-type epitaxial pattern, wherein the central insulating layer extends in the second direction and is in the opening, and wherein the opening overlaps, in the third direction, with an interface between the first conductivity-type impurity region and the second conductivity-type impurity region.

According to some example embodiments of the present disclosure, a semiconductor device may include: a substrate; an active pattern extending in a first direction on a first surface of the substrate, the active pattern including at least one conductivity-type impurity region; a first conductivity-type epitaxial pattern on the at least one conductivity-type impurity region; a second conductivity-type epitaxial pattern on the at least one conductivity-type impurity region, and spaced apart from the first conductivity-type epitaxial pattern in the first direction; an interlayer insulating layer on the first surface of the substrate, the first conductivity-type epitaxial pattern, and the second conductivity-type epitaxial pattern; an intermediate insulating layer including an opening extending in a second direction, intersecting the first direction, the intermediate insulating layer being on the interlayer insulating layer; a central insulating layer between the first conductivity-type epitaxial pattern and the second conductivity-type epitaxial pattern, wherein the central insulating layer extends in the second direction and is in the opening; contact structures penetrating through the interlayer insulating layer and the intermediate insulating layer and respectively in contact with the first conductivity-type epitaxial pattern and the second conductivity-type epitaxial pattern; an upper interconnection structure including an upper via and an upper metal line, the upper via and the upper metal line being on at least one of the contact structures; and a lower interconnection structure including a lower via and a lower metal line, the lower via and the lower metal line being on a second surface of the substrate, opposite to the first surface, wherein the at least one conductivity-type impurity region includes a first conductivity-type impurity region and a second conductivity-type impurity region in contact with each other in the first direction, and wherein the opening overlaps, in a third direction intersecting the first direction and the second direction, with an interface between the first conductivity-type impurity region and the second conductivity-type impurity region.

### BRIEF DESCRIPTION OF DRAWINGS

The above and other aspects, features, and advantages of embodiments of the present disclosure will be more clearly understood from the following detailed description, taken in combination with the accompanying drawings, in which:

FIG. 1 is a plan diagram illustrating a semiconductor device according to some example embodiments of the present disclosure;

FIG. 2 is a cross-sectional diagram illustrating a first device of a semiconductor device taken along a line I-I′ in FIG. 1 according to an example embodiment of the present disclosure;

FIG. 3 is a cross-sectional diagram illustrating a first device of a semiconductor device taken along a line II-II′ in FIG. 1 according to an example embodiment of the present disclosure;

FIG. 4 is a cross-sectional diagram illustrating a first device of a semiconductor device taken along a line III-III′ in FIG. 1 according to an example embodiment of the present disclosure;

FIG. 5 is a cross-sectional diagram illustrating a second device of a semiconductor device taken along a line IV-IV′ in FIG. 1 according to an example embodiment of the present disclosure;

FIG. 6 is a cross-sectional diagram illustrating a second device of a semiconductor device taken along a line V1A-V1A′ in FIG. 1 according to an example embodiment of the present disclosure;

FIG. 7 is a cross-sectional diagram illustrating a second device of a semiconductor device taken along a line V1B-V1B′ in FIG. 1 according to an example embodiment of the present disclosure;

FIG. 8 is a cross-sectional diagram illustrating a second device of a semiconductor device taken along a line V2A-V2A′ in FIG. 1 according to an example embodiment of the present disclosure;

FIG. 9 is a cross-sectional diagram illustrating a second device of a semiconductor device taken along a line V2B-V2B′ in FIG. 1 according to an example embodiment of the present disclosure;

FIG. 10 is a cross-sectional diagram illustrating a first device of a semiconductor device taken along a line I-I′ in FIG. 1 according to an example embodiment of the present disclosure;

FIG. 11 is a cross-sectional diagram illustrating a first device of a semiconductor device taken along a line II-II′ in FIG. 1 according to an example embodiment of the present disclosure;

FIG. 12 is a cross-sectional diagram illustrating a second device of a semiconductor device taken along a line IV-IV′ in FIG. 1 according to an example embodiment of the present disclosure;

FIG. 13 is a cross-sectional diagram illustrating a second device of a semiconductor device taken along a line IV-IV′ in FIG. 1 according to an example embodiment of the present disclosure;

FIG. 14 is a cross-sectional diagram illustrating a second device of a semiconductor device taken along a line IV-IV′ in FIG. 1 according to an example embodiment of the present disclosure;

FIG. 15 is a flowchart illustrating a method of manufacturing a semiconductor device according to some example embodiments of the present disclosure;

FIGS. 16A, 16B, 17A, 17B, 18A, 18B, 19A, 19B, 20A, 20B, 21A, 21B, 22A, 22B, 23A, 23B, 24A, 24B, 25A, 25B, 26A, 26B, 27A, 27B, 28A, 28B, 29A, 29B, 30A, 30B, 31A, 31B, 32A, 32B, 33A, and 33B are diagrams illustrating an intermediate process of a method of manufacturing a semiconductor device according to some example embodiments of the present disclosure; and

FIG. 34 is a block diagram illustrating an electronic device including a semiconductor device according to some example embodiments of the present disclosure.

### DETAILED DESCRIPTION

Hereinafter, non-limiting example embodiments of the present disclosure will be described as follows with reference to the accompanying drawings.

In the drawings, the portions not related to the description may not be illustrated, and same or similar elements will be indicated by same or similar reference numerals.

Also, a size, thickness, and ratio of each element illustrated in the drawings may be arbitrarily illustrated for ease of description, and embodiments of the present disclosure are not limited to the elements illustrated in the drawings. For ease of description and/or simplified illustration, the thicknesses of a portion of layers and regions may be enlarged or exaggerated.

When it is described that an element, layer, pattern, structure, region, or the like (hereinafter collectively referred to as “element”) of the present disclosure is referred to as being disposed “over,” “above,” “on,” “below,” “under,” “beneath,” “connected to,” or “coupled to or combined to” another element, the element may be disposed directly over, above, on, below, under, beneath, connected to, or combined to the other element, or an intermediate element may be present. When an element of the present disclosure is disposed “directly over,” “directly above,” “directly on,” “directly below,” “directly under,” “directly beneath,” “directly connected to,” or “directly coupled to or directly combined to” another element of the present disclosure, no intermediate element is provided.

In this disclosure, terms such as “first,” “second,” or the like are used to describe various elements, and these elements are not limited to the terms. It should be understood that these terms are used only to distinguish one element from another.

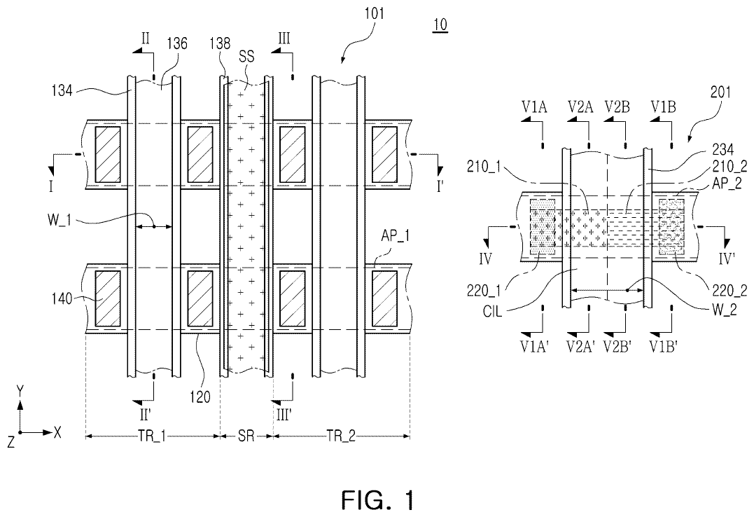

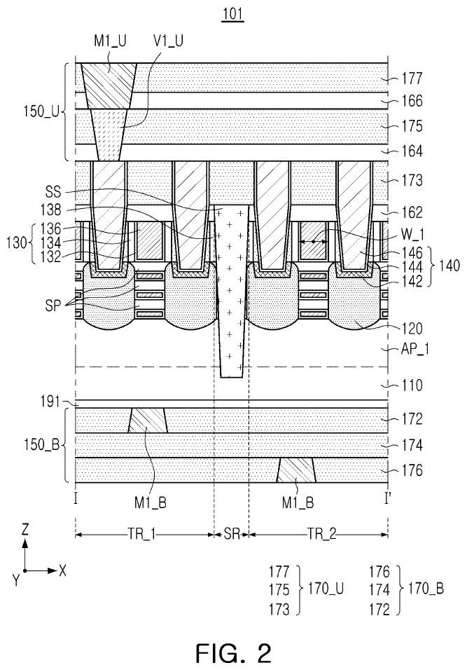

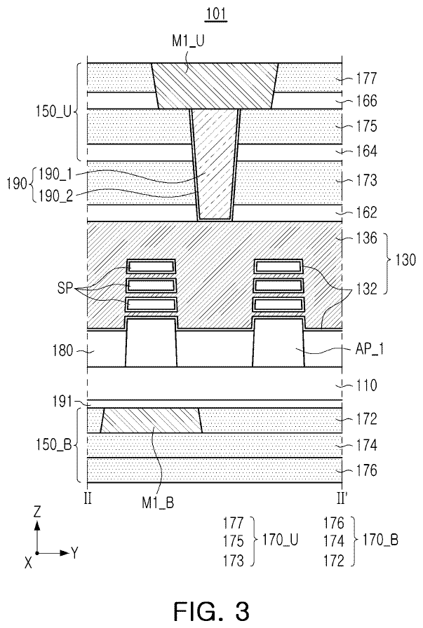

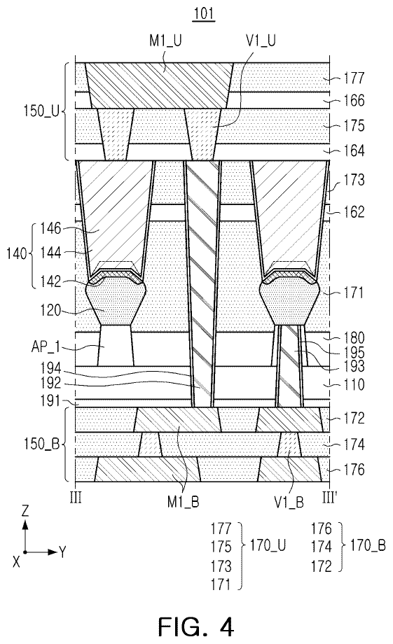

FIG. 1 is a plan diagram illustrating a semiconductor device according to some example embodiments. FIG. 2 is a cross-sectional diagram illustrating a first device of a semiconductor device taken along a line I-I′ in FIG. 1 according to an example embodiment. FIG. 3 is a cross-sectional diagram illustrating a first device of a semiconductor device taken along a line II-II′ in FIG. 1 according to an example embodiment. FIG. 4 is a cross-sectional diagram illustrating a first device of a semiconductor device taken along a line III-III′ in FIG. 1 according to an example embodiment. Referring to FIGS. 1 to 4, a semiconductor device 10 may include a substrate 110. Hereinafter, the substrate 110 may have a first surface (or an upper surface) and a second surface (or a lower surface) opposing the first surface. In some example embodiments, the substrate 110 may include a semiconductor material, such as a group IV semiconductor, a group III-V compound semiconductor, or a group II-VI compound semiconductor. For example, the group IV semiconductor may include silicon (Si), germanium (Ge), or silicon-germanium (Si—Ge). For example, the group III-V compound semiconductor may include gallium phosphide (GaP), gallium-arsenide (GaAs), indium-arsenide (InAs), aluminum-gallium-arsenide (AlGaAs), or indium phosphide (InP). For example, the group II-VI compound semiconductor may include zinc sulfide (ZnS), zinc selenide (ZnSe), cadmium sulfide (CdS), or cadmium selenide (CdSe). The substrate 110 may further include impurities. The substrate 110 may include a silicon substrate, a silicon-on-insulator (SOI) substrate, a germanium substrate, a germanium on insulator (GOI) substrate, or an epitaxial layer.

The semiconductor device 10 may include a first device 101 and a second device 201 arranged in a horizontal direction (e.g., X-direction or Y-direction) on the substrate 110. The first device 101 and the second device 201 may be spaced apart from each other in the horizontal direction. For example, the second device 201 may be spaced apart from the first device 101 in the first direction (e.g., X-direction) or a second direction (e.g., Y-direction) intersecting the first direction. The first device 101 and the second device 201 may include active patterns (e.g., a first active pattern AP_1 and a second active pattern AP_2). In example embodiments, the same or similar elements of the first device 101 and the second device 201 may be formed by the same process.

The first device 101 of the semiconductor device 10 may include a plurality of transistors. The first device 101 may include a plurality of regions including transistors, respectively. The first device 101 may include other regions which may isolate individual transistors. For example, the first device 101 may include a first transistor region TR_1, a second transistor region TR_2 and an isolation region SR defined on the substrate 110. Here, the isolation region SR may be disposed between the first transistor region TR_1 and the second transistor region TR_2. In some example embodiments, the first device 101 may include elements including various types of transistors, such as a gate-all-around field effect transistor (GAAFET), a multi-bridge-channel field effect transistor (MBCFET), or a fin field effect transistor (FinFET).

The first transistor region TR_1 and the second transistor region TR_2 may include a first active pattern AP_1, a plurality of semiconductor patterns SP, a plurality of source/drain patterns 120, a plurality of gate structures 130, a plurality of source/drain contacts 140, or the like. The first transistor region TR_1 and the second transistor region TR_2 may be N-type metal-oxide-semiconductor (NMOS) and P-type metal-oxide-semiconductor (PMOS) regions, respectively, or the same type of transistor regions. The isolation region SR may isolate the first transistor region TR_1 and the second transistor region TR_2 from each other in a horizontal direction (e.g., X-direction). The isolation region SR may include an isolation structure SS and isolation spacer layers 138, or the like.

The first active pattern AP_1 may extend in the first direction (e.g., X-direction) along the first surface of the substrate 110. For example, the first active pattern AP_1 may have a fin-shaped structure extending in the first direction (e.g., X-direction) along the first surface of the substrate 110. For example, the first active pattern AP_1 may protrude in a direction (e.g., Z-direction) perpendicular to the first direction (e.g., X-direction) from the first surface of the substrate 110. Here, the first surface of the substrate 110 may be an upper surface of the substrate 110 with respect to the first device 101 illustrated in FIG. 2. The upper surface of the substrate 110 may be a surface positioned at a level higher than a level of a lower surface of the substrate 110 in the vertical direction (e.g., Z-direction). The first active pattern AP_1 may be configured as a portion of the substrate 110 and may include an epitaxial layer grown from the substrate 110. The first active pattern AP_1 may include impurities or may include a doping region including impurities.

In some example embodiments, the first device 101 may further include an element isolation layer 180. The element isolation layer 180 may define the first active pattern AP_1 on the substrate 110. For example, the element isolation layer 180 may be formed by a shallow trench isolation (STI) process. An upper surface of the element isolation layer 180 may be positioned at a level lower than a level of an upper surface of the first active pattern AP_1 in the vertical direction (e.g., Z-direction). That is, the first active pattern AP_1 may be formed to protrude more than the element isolation layer 180 from the first surface of the substrate 110. The element isolation layer 180 may have a curved upper surface positioned at a higher level as the upper surface of the element isolation layer 180 becomes closer to the first active pattern AP_1. The element isolation layer 180 may be formed of an insulating material. For example, the element isolation layer 180 may be formed of at least one from among silicon oxide, silicon nitride, and a combination thereof.

A plurality of semiconductor patterns SP may be disposed on the first active pattern AP_1. A plurality of semiconductor patterns SP may be spaced apart from each other in a direction perpendicular to the first surface of the substrate 110, that is, a third direction (e.g., Z-direction) on the first active pattern AP_1. The first active pattern AP_1 and a plurality of semiconductor patterns SP may be provided as multiple channel layers of the transistor. In example embodiments, the number of the semiconductor patterns SP may be three, but the number of the semiconductor patterns SP may not be limited thereto. The semiconductor patterns SP may be formed of a semiconductor material. For example, the semiconductor patterns SP may include at least one from among silicon and silicon-germanium (SiGe). The semiconductor patterns SP may also be formed of the same material as a material of the substrate 110.

The plurality of source/drain patterns 120 may be disposed on at least one side of the semiconductor pattern SP. Alternatively, the plurality of source/drain patterns 120 may be disposed on the first active pattern AP_1. The source/drain patterns 120 may cover the upper surface of the first active pattern AP_1 below side surfaces of the semiconductor patterns SP and the source/drain patterns 120, respectively. The source/drain patterns 120 may be recessed into at least a portion of the upper surface of the first active pattern AP_1. Here, whether the first active pattern AP_1 is recessed and the recessed depth may be varied. Each of the source/drain patterns 120 may be a semiconductor layer including silicon (Si) and may include impurities having different types and/or concentrations.

In some example embodiments, the source/drain patterns 120 may include an epitaxial pattern selectively epitaxially grown (SEG) from the recessed surface of the first active pattern AP_1 and side surfaces of the plurality of semiconductor patterns SP on both sides of the gate structure 130. For example, the source/drain patterns 120 may be Si, SiGe or Ge and may have a N-type conductivity or a P-type conductivity. In some example embodiments, when the source/drain patterns 120 are source/drains having N-type conductivity, the source/drain patterns 120 may include silicon (Si) doped with N-type impurities, such as phosphorus (P), nitrogen (N), arsenic (As) and/or antimony (Sb). Also, when the source/drain patterns 120 are source/drains having P-type conductivity, the source/drain patterns 120 may include silicon (Si) or silicon germanium (SiGe) doped with N-type impurities such as boron (B), indium (In), gallium (Ga), and/or boron trifluoride (BF₃).

The source/drain patterns 120 may have different shapes along the crystallographically stable surface during a growth process. For example, the source/drain patterns 120 having N-type conductivity may have a cross-sectional surface having a hexagonal shape or various other polygonal shapes with gentle angles, and the source/drain patterns 120 having P-type conductivity may have a cross-sectional surface having a pentagonal shape or various other polygonal shapes.

A plurality of gate structures 130 may intersect the first active pattern AP_1 and the semiconductor patterns SP on the first active pattern AP_1 and the semiconductor patterns SP and may extend in the second direction (e.g., Y-direction) intersecting the first direction (e.g., X-direction). For example, a channel region of transistors may be formed on the first active pattern AP_1 and the semiconductor patterns SP intersecting the gate structure 130.

Each of the plurality of gate structures 130 may include a gate dielectric layer 132, gate spacer layers 134 and a gate electrode 136. The gate dielectric layer 132 and the gate electrode 136 may be disposed in order between the gate spacer layers 134. For example, the gate spacer layers 134 may be disposed on a side surface of the gate electrode 136. The gate dielectric layer 132 may be disposed between the first active pattern AP_1 and the gate electrode 136 and between the semiconductor patterns SP and the gate electrode 136. The gate dielectric layer 132 may be disposed to surround the entirety of surfaces other than an uppermost surface of the gate electrode 136. The gate dielectric layer 132 may cover the first active pattern AP_1 and an upper surface of the element isolation layer 180 on the first surface of the substrate 110. The gate dielectric layer 132 may be disposed to surround the semiconductor patterns SP. The gate dielectric layer 132 may extend between the gate electrode 136 and the gate spacer layers 134, but an example embodiment thereof is not limited thereto. The gate dielectric layer 132 may include a silicon oxide film, a high-k film, or a combination thereof. The high-k film may include a material having a dielectric constant higher than a dielectric constant of the silicon oxide film. For example, a dielectric constant of the high-k film may be about 10 to 25. The high-k film may be formed of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃), or combinations thereof, but an example embodiment thereof is not limited thereto.

The gate spacer layers 134 may be disposed on both side surfaces of the gate electrode 136 and may extend in a direction perpendicular to the first surface of the substrate 110 (e.g., Z-direction). The gate spacer layers 134 may be disposed on both side surfaces of the gate electrode 136. The gate spacer layers 134 may insulate the source/drain patterns 120 and the gate electrode 136 from each other. The gate spacer layers 134 may be configured as a multilayer structure. The gate spacer layers 134 may be formed of at least one from among oxide, nitride, oxynitride, and silicon nitride materials.

The gate electrode 136 may fill a gap between the semiconductor patterns SP on the first active pattern AP_1 and may extend to an upper portion of the semiconductor patterns SP. The gate electrode 136 may intersect the semiconductor patterns SP and may extend in the second direction (e.g., Y-direction) intersecting the first direction. The gate electrode 136 may surround the semiconductor patterns SP. The gate electrode 136 may be spaced apart from the semiconductor patterns SP by a gate dielectric layer 132. The gate electrode 136 may include a conductive material. For example, the gate electrode 136 may include a metal nitride such as a titanium nitride (TiN), a tantalum nitride (TaN), or a tungsten nitride (WN), and/or a metal material such as aluminum (Al), tungsten (W), or molybdenum (Mo), or a semiconductor material such as doped polysilicon. The gate electrode 136 may be configured as multiple layers. The gate electrode 136 may have a width W_1 extending in the first direction (e.g., X-direction) between the gate spacer layers 134.

According to some embodiments, the gate structure 130 may further include a gate capping layer. In this case, the gate capping layer may be disposed on the gate electrode 136. The gate capping layer may be disposed to extend in the second direction (e.g., Y-direction) along the upper surface of the gate electrode 136. The gate capping layer may include a first material, which may be a silicon nitride material. The silicon nitride material may be, for example, SiN, SiCN, SiON, and SiOCN.

The isolation structure SS may be disposed between adjacent first active patterns AP_1, between adjacent second active patterns AP_2, and between adjacent source/drain patterns 120. The isolation structure SS may extend in the second direction (e.g., Y-direction). The upper surface of the isolation structure SS may be disposed at the same level as a level of the upper surface of the gate structure 130. The upper surface of the isolation structure SS may be disposed at a level higher than a level of the upper surface of the gate structure 130. The isolation structure SS may have a tapered shape in which a width of a lower portion in the second direction (e.g., Y-direction) is narrower than a width of an upper portion in the second direction depending on the aspect ratio, but an example embodiment thereof is not limited thereto. The lower surface of the isolation structure SS may be a flat surface, or may have a curved shape or a pointed shape facing the substrate 110, or the like, but an example embodiment thereof is not limited thereto.

In some example embodiments, a lower end of the isolation structure SS may be positioned at a level lower than a lower end of the first active pattern AP_1 by a predetermined depth. For example, the isolation structure SS may extend from an upper portion toward the substrate 110 in the third direction (e.g., Z-direction) intersecting each of the first direction (e.g., X-direction) and the second direction (e.g., Y-direction), and may be recessed into the first active pattern AP_1. A lower surface of the isolation structure SS may be positioned at a level lower than a level of a lower surface of the first active pattern AP_1. A lower surface of the isolation structure SS may be positioned at a level lower than a level of a lower surface of the source/drain patterns 120. The isolation structure SS may include at least one from among oxide, nitride, oxynitride, and silicon nitride family materials. In some example embodiments, the gate structures 130 adjacent to both side surfaces of the isolation structure SS may be dummy gate structures. However, an example embodiment thereof is not limited thereto.

The isolation spacer layers 138 may be positioned at the same level in the direction perpendicular to the gate spacer layers 134 and the first surface of the substrate 110 (e.g., Z-direction), and may be disposed on both side surfaces of the isolation structure SS. The isolation spacer layers 138 may have a shape that is the same as a shape in which the gate spacer layers 134 are removed from one side surface in the first direction by a predetermined width. One side surface of the isolation spacer layers 138 may include an inclined surface with respect to the substrate 110. However, the shape of the isolation spacer layers 138 is not limited thereto, and may have the same shape as that of the gate spacer layers 134. In example embodiments, the isolation spacer layers 138 may be formed as a multilayer structure. In another example embodiment, the isolation spacer layers 138 may not be provided. An upper surface of the isolation spacer layers 138 may be disposed at a level lower than a level of an upper surface of the isolation structure SS in the third direction (e.g., Z-direction). The upper surface of the isolation spacer layers 138 may be disposed at a level lower than a level of the upper surface of the gate spacer layers 134 in the third direction (e.g., Z-direction). The isolation spacer layers 138 may include the same material as a material of the gate spacer layers 134. For example, the isolation spacer layers 138 may include at least one from among oxide, nitride, oxynitride, and silicon nitride materials.

The source/drain contacts 140 may be disposed on the source/drain patterns 120 and may be connected to the source/drain patterns 120. The source/drain contacts 140 may be in contact with the source/drain patterns 120 and may apply an electrical signal. The source/drain contacts 140 may be disposed to have a longer length in the second direction (e.g., Y-direction) than a length of the source/drain patterns 120. The source/drain contacts 140 may have an inclined side surface such that a width of a lower portion thereof is narrower than a width of an upper portion thereof depending on an aspect ratio, but an example embodiment thereof is not limited thereto. For example, the source/drain contacts 140 may be recessed into the source/drain patterns 120 and may be in contact with the source/drain patterns 120, but an example embodiment thereof is not limited thereto. For example, the source/drain contacts 140 may be disposed not to be recessed into the source/drain patterns 120, and to be in contact with the upper surface of the source/drain patterns 120.

An upper surface of each of the source/drain contacts 140 may be positioned at the same level as a level of the upper surface of the gate structure 130 in the third direction (e.g., Z-direction), but an example embodiment thereof is not limited thereto. The upper surface of at least one of the source/drain contacts 140 may be disposed at a level higher than a level of the upper surface of the isolation structure SS in the third direction (e.g., Z-direction). The upper surface of the source/drain contacts 140 may be positioned at a level higher than a level of the isolation spacer layers 138 in the third direction (e.g., Z-direction).

In some example embodiments, the first device 101 may further include a gate contact 190. The gate contact 190 may be disposed on the first surface of the substrate 110. The gate contact 190 may be electrically connected to the gate electrode 136.

Each of the source/drain contacts 140 may include a conductive material 146, and a conductive barrier 144 surrounding a side surface and a lower surface of the conductive material 146. For example, the conductive material 146 may include Cu, Co, Mo, Ru, W, or an alloy thereof. For example, the conductive barrier 144 may include Ta, TaN, Mn, MnN, WN, Ti, TiN, or a combination thereof. In some example embodiments, each of the source/drain contacts 140 may further include a metal silicide film 142 formed on the source/drain patterns 120 to improve contact resistance. The gate contact 190 may also include the conductive material 190_1 and the conductive barrier 190_2 having the same configuration as the conductive material 146 and the conductive barrier 144 described above.

In some example embodiments, the semiconductor device 10 may further include a plurality of intermediate insulating layers (e.g., a first intermediate insulating layer 162, a second intermediate insulating layer 164, and a third intermediate insulating layer 166) and a plurality of interlayer insulating layers (e.g., first through seventh interlayer insulating layers 171-177). The plurality of intermediate insulating layers (e.g., the first intermediate insulating layer 162, the second intermediate insulating layer 164, and the third intermediate insulating layer 166) and the plurality of interlayer insulating layers (e.g., the first through seventh interlayer insulating layers 171-177) may be commonly formed in the first device 101 and the second device 201. The plurality of intermediate insulating layers (e.g., the first intermediate insulating layer 162, the second intermediate insulating layer 164, and the third intermediate insulating layer 166) and the plurality of interlayer insulating layers (e.g., the first through seventh interlayer insulating layers 171-177) may be formed simultaneously in the first device 101 and the second device 201. In example embodiments, the first interlayer insulating layer 171, the second interlayer insulating layer 173, the third interlayer insulating layer 175 and the fourth interlayer insulating layer 177 may be defined as an upper interlayer insulating layer 170_U. Here, the upper interlayer insulating layer 170_U may include interlayer insulating layers disposed on the first surface of the substrate 110. Also, in example embodiments, the fifth interlayer insulating layer 172, the sixth interlayer insulating layer 174 and the seventh interlayer insulating layer 176 may be defined as a lower interlayer insulating layer 170_B. Here, the lower interlayer insulating layer 170_B may be interlayer insulating layers disposed on the second surface of the substrate 110.

The first intermediate insulating layer 162 may be disposed on the first surface of the substrate 110. The first intermediate insulating layer 162 may be disposed on the first interlayer insulating layer 171 and the gate structure 130. The first intermediate insulating layer 162 may be disposed on the first interlayer insulating layer 171. The second intermediate insulating layer 164 may be disposed on the first intermediate insulating layer 162 and the second interlayer insulating layer 173. The third intermediate insulating layer 166 may be disposed on the second intermediate insulating layer 164 and the third interlayer insulating layer 175.

The first interlayer insulating layer 171 may be disposed on a first surface of a substrate 110. The first interlayer insulating layer 171 may cover source/drain patterns 120 and gate structures 130. A second interlayer insulating layer 173 may be disposed on the first interlayer insulating layer 171 and the first intermediate insulating layer 162. A third interlayer insulating layer 175 may be disposed on the second interlayer insulating layer 173 and the second intermediate insulating layer 164. A fourth interlayer insulating layer 177 may be disposed on the third interlayer insulating layer 175 and the third intermediate insulating layer 166.

The fifth interlayer insulating layer 172 may be disposed on the second surface of the substrate 110. The sixth interlayer insulating layer 174 may be disposed on the fifth interlayer insulating layer 172. The seventh interlayer insulating layer 176 may be disposed on the sixth interlayer insulating layer 174. The fifth to seventh interlayer insulating layers 172, 174, and 176 may be formed during the backside process together with a lower interconnection structure 150_B.

In some example embodiments, the isolation structure SS may penetrate the first interlayer insulating layer 171 and the first intermediate insulating layer 162. The isolation structure SS may be formed of the same material as a material of the first intermediate insulating layer 162, but an example embodiment thereof is not limited thereto. In some example embodiments, the source/drain contacts 140 may penetrate the first interlayer insulating layer 171, the first intermediate insulating layer 162, and the second interlayer insulating layer 173. The gate contact 190 may penetrate the first intermediate insulating layer 162, the second interlayer insulating layer 173, the second intermediate insulating layer 164, and the third interlayer insulating layer 175.

In some example embodiments, the first device 101 may include an upper interconnection structure 150_U disposed on the first surface of the substrate 110, and a lower interconnection structure 150_B disposed on the second surface of the substrate 110. For example, each of the interconnection structures may be formed by a dual damascene process. The upper interconnection structure 150_U may include a plurality of first upper vias V1_U and a plurality of first upper metal lines M1_U. The plurality of first upper vias V1_U may penetrate the second intermediate insulating layer 164 and the third interlayer insulating layer 175 and may be connected to the source/drain contacts 140. However, an example embodiment thereof is not limited thereto, and the plurality of first upper vias V1_U may penetrate at least the second intermediate insulating layer 164 and may be connected to the source/drain contacts 140. For example, the first upper via V1_U may be in contact with one source/drain contact 140. The plurality of first upper vias V1_U may have a side surface inclined such that a width of a lower portion thereof may be narrower than a width of an upper portion thereof depending on an aspect ratio, but an example embodiment thereof is not limited thereto.

The lower interconnection structure 150_B may include a plurality of first lower vias V1_B and a plurality of first lower metal lines M1_B. The plurality of first lower vias V1_B may penetrate the sixth interlayer insulating layer 174 and may connect the plurality of first lower metal lines M1_B to each other. The first lower via V1_B may have a side surface inclined such that a width of a lower portion thereof is narrower than a width of an upper portion thereof depending on an aspect ratio, but an example embodiment thereof is not limited thereto.

The first device 101 may include power transfer structures for supplying power to each of transistor cells from the second surface of the substrate 110. For example, the power transfer structures may include a plurality of through-buried structures (e.g., a first through-buried structure 192 and a second through-buried structure 193) arranged in the second direction (e.g., Y-direction) and a plurality of through-insulating layers 194 and 195 surrounding a bottom surface and a side surface of the plurality of through-buried structures (e.g., the first through-buried structure 192 and the second through-buried structure 193).

For example, the first through-buried structure 192 may extend from the upper interconnection structure 150_U in the third direction (e.g., Z-direction), may penetrate the substrate 110, and may be connected to the lower interconnection structure 150_B. The first through-buried structure 192 may penetrate the second interlayer insulating layer 173, the first intermediate insulating layer 162, the first interlayer insulating layer 171, the element isolation layer 180, the substrate 110, and the insulating protective layer 191, and may be connected to the lower interconnection structure 150_B. The first through-buried structure 192 may be electrically connected to the source/drain patterns 120 by the first upper metal line M1_U, which may be a power line of the upper interconnection structure 150_U. The first through-buried structure 192 may be electrically connected to the source/drain patterns 120 by the first lower metal line M1_B.

The second through-buried structure 193 may extend from the lower interconnection structure 150_B in the third direction (e.g., Z-direction), may penetrate the substrate 110 and the first active pattern AP_1, and may be in contact with the source/drain patterns 120. The second through-buried structure 193 may receive power from the first lower metal line M1_B and may supply power to the source/drain patterns 120 of the first device 101.

The plurality of through-buried structures (e.g., the first through-buried structure 192 and the second through-buried structure 193) may include Cu, Co, Mo, Ru, W, or an alloy thereof. The plurality of through-insulating layers 194 and 195 may include SiO₂, SiN, SiCN, SiC, SiCOH, SiON, Al₂O₃, AlN, or a combination thereof.

In some example embodiments, an insulating protective layer (or etching stop layer) 191 may be disposed on the second surface (or a lower surface) of the substrate 110. The insulating protective layer 191 may surround a contact region of a through-buried structure (e.g., the first through-buried structure 192 and the second through-buried structure 193) protruding from the second surface of the substrate 110. A lower interconnection structure 150_B may be disposed on the insulating protective layer 191. The lower interconnection structure 150_B may include a plurality of first lower vias V1_B and a plurality of first lower metal lines M1_B buried in the lower interlayer insulating layer 170_B.

In some example embodiments, the lower interconnection structure 150_B may further include an additional interconnection layer, and may be configured to interconnect the first device 101 and the second device 201 with power lines and signal lines. The insulating protective layer 191 may include the same insulating material as an insulating material of the lower interlayer insulating layer 170_B. The insulating protective layer 191 may include an insulating material different from an insulating material of the lower interlayer insulating layer 170_B. For example, the insulating protective layer 191 may include AlN or SiN.

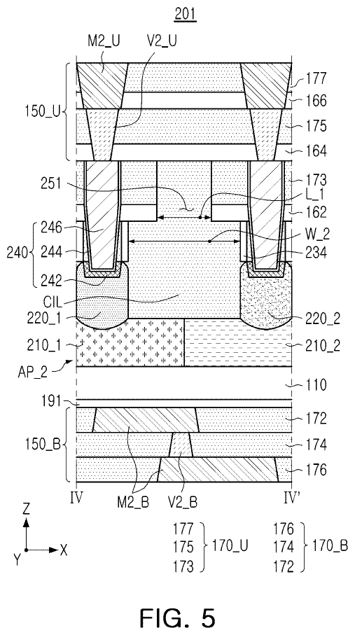

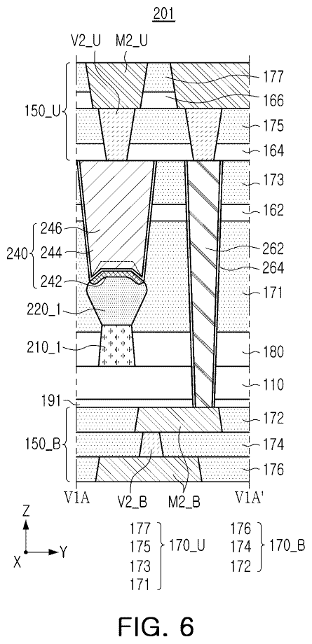

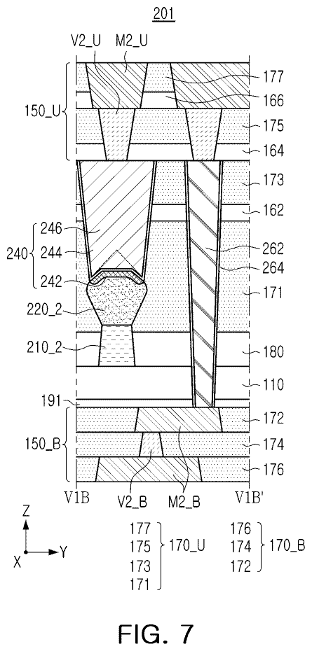

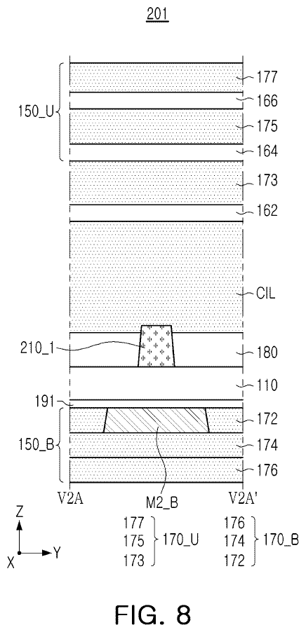

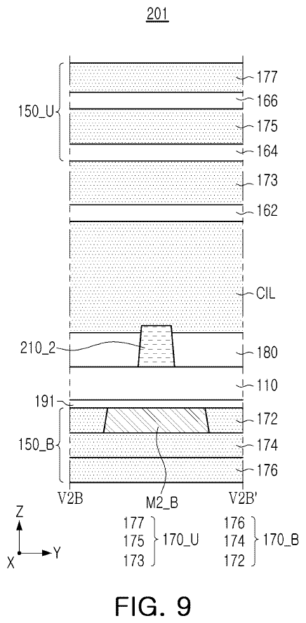

FIG. 5 is a cross-sectional diagram illustrating a second device of a semiconductor device taken along a line IV-IV′ in FIG. 1 according to an example embodiment; FIG. 6 is a cross-sectional diagram illustrating a second device of a semiconductor device taken along a line V1A-V1A′ in FIG. 1 according to an example embodiment; FIG. 7 is a cross-sectional diagram illustrating a second device of a semiconductor device taken along a line V1B-V1B′ in FIG. 1 according to an example embodiment; FIG. 8 is a cross-sectional diagram illustrating a second device of a semiconductor device taken along a line V2A-V2A′ in FIG. 1 according to an example embodiment; FIG. 9 is a cross-sectional diagram illustrating a second device of a semiconductor device taken along a line V2B-V2B′ in FIG. 1 according to an example embodiment. For ease of description, repeated description of the same as or similar elements to the elements described in the example embodiments described with reference to FIGS. 1 to 4 may not be provided. Referring to FIGS. 5 to 9, the second device 201 of the semiconductor device 10 may include a second active pattern AP_2 including conductivity impurity regions (e.g., a first conductivity-type impurity region 210_1 and a second conductivity-type impurity region 210_2), a first conductivity-type epitaxial pattern 220_1, a second conductivity-type epitaxial pattern 220_2, a first intermediate insulating layer 162, an upper interlayer insulating layer 170_U, a lower interlayer insulating layer 170_B, a central insulating layer CIL, contact structures 240, or the like. The upper interlayer insulating layer 170_U may include first to fourth interlayer insulating layers 171, 173, 175, and 177. The lower interlayer insulating layer 170_B may include fifth to seventh interlayer insulating layers 172, 174, and 176. In some example embodiments, the second device 201 may include a diode.

The second active pattern AP_2 may extend in the first direction (e.g., X-direction) along the first surface of the substrate 110 and may include conductivity impurity regions (e.g., the first conductivity-type impurity region 210_1 and the second conductivity-type impurity region 210_2) disposed in the first direction. The first conductivity-type impurity region 210_1 and the second conductivity-type impurity region 210_2 may be formed to protrude further than the element isolation layer 180 formed on the second device 202 in a direction perpendicular to the first surface of the substrate 110 (e.g., Z-direction). The first conductivity-type impurity region 210_1 and the second conductivity-type impurity region 210_2 may be provided as impurity regions included in the second device 201. That is, the first conductivity-type impurity region 210_1 and the second conductivity-type impurity region 210_2 may include impurities. The impurities may include N-type impurities or P-type impurities.

For example, the first conductivity-type impurity region 210_1 and the second conductivity-type impurity region 210_2 may be formed by performing a selective ion implantation process on the second active pattern AP_2 of the second device 201. The ion implantation process for forming the conductivity-type impurity regions (e.g., the first conductivity-type impurity region 210_1 and the second conductivity-type impurity region 210_2) on the second active pattern AP_2 may be performed before the semiconductor patterns SP of the first device 101 illustrated in FIG. 2 is formed.

In some example embodiments, the first conductivity-type impurity region 210_1 may be a P-type region, and the second conductivity-type impurity region 210_2 may be an N-type region. Alternatively, the first conductivity-type impurity region 210_1 may be an N-type region, and the second conductivity-type impurity region 210_2 may be a P-type region. In this case, the first conductivity-type impurity region 210_1 and the second conductivity-type impurity region 210_2 may be in contact with each other in the first direction (e.g., X-direction) and may form a p-n bonding structure. Accordingly, the second device 201 may include a diode, and may be implemented with various semiconductor elements including a p-n bonding structure, a p-n-p bonding structure, an n-p-n bonding structure, or the like.

The first conductivity-type epitaxial pattern 220_1 and the second conductivity-type epitaxial pattern 220_2 may be disposed on the first surface of the substrate 110. The first conductivity-type epitaxial pattern 220_1 and the second conductivity-type epitaxial pattern 220_2 may be disposed on the first conductivity-type impurity region 210_1 and the second conductivity-type impurity region 210_2 of the second active pattern AP_2, respectively. The first conductivity-type epitaxial pattern 220_1 and the second conductivity-type epitaxial pattern 220_2 may be connected to both side surfaces of the central insulating layer CIL in the first direction (e.g., X-direction), respectively. The first conductivity-type epitaxial pattern 220_1 and the second conductivity-type epitaxial pattern 220_2 may be spaced apart from each other in the first direction (e.g., X-direction).

In some example embodiments, the first conductivity-type epitaxial pattern 220_1 and the second conductivity-type epitaxial pattern 220_2 may include impurities. The impurities may include N-type impurities or P-type impurities. For example, the first conductivity-type epitaxial pattern 220_1 and the first conductivity-type impurity region 210_1 may be N-type regions, and the second conductivity-type epitaxial pattern 220_2 and the second conductivity-type impurity region 210_2 may be P-type regions. For example, the first conductivity-type epitaxial pattern 220_1 may be a P-type epitaxial pattern, and the first conductivity-type impurity region 210_1 may be a P-type region. In this case, the second conductivity-type epitaxial pattern 220_2 may be an N-type epitaxial pattern, and the second conductivity-type impurity region 210_2 may be an N-type region.

In some example embodiments, a concentration of impurities in the first conductivity-type epitaxial pattern 220_1 may be higher than a concentration of impurities in the first conductivity-type impurity region 210_1. A concentration of impurities in the second conductivity-type epitaxial pattern 220_2 may be higher than a concentration of impurities in the second conductivity-type impurity region 210_2. When the first conductivity-type impurity region 210_1 and the second conductivity-type impurity region 210_2 form a p-n bonding structure, the first conductivity-type epitaxial pattern 220_1 and the second conductivity-type epitaxial pattern 220_2 may function as electrical paths for the first conductivity-type impurity region 210_1 and the second conductivity-type impurity region 210_2, respectively. For example, the first conductivity-type impurity region 210_1 may receive an electrical signal from the upper interconnection structure 150_U through the contact structure 240 and the first conductivity-type epitaxial pattern 220_1. For example, the second conductivity-type impurity region 210_2 may receive an electrical signal from the upper interconnection structure 150_U through the contact structure 240 and the second conductivity-type epitaxial pattern 220_2. In some example embodiments, when the first conductivity-type impurity region 210_1 is an N-type region and the first conductivity-type epitaxial pattern 220_1 may be an N-type epitaxial pattern, the first conductivity-type impurity region 210_1 and the first conductivity-type epitaxial pattern 220_1 may be a cathode of a diode. When the second conductivity-type impurity region 210_2 is a P-type region and the second conductivity-type epitaxial pattern 220_2 is a P-type epitaxial pattern, the second conductivity-type impurity region 210_2 and the second conductivity-type epitaxial pattern 220_2 may be anodes of a diode.

The first conductivity-type epitaxial pattern 220_1 and the second conductivity-type epitaxial pattern 220_2 may be formed in the process of forming the source/drain patterns 120 of the first device 101. In some example embodiments, a portion of the first conductivity-type epitaxial pattern 220_1 and the source/drain patterns 120 may be N-type epitaxial having the same composition as each other. Also, the other portion of the second conductivity-type epitaxial pattern 220_2 and the source/drain patterns 120 may be P-type epitaxial having the same composition as each other. This process may be performed by a selective epitaxial growth (SEG) process as described above. Specifically, the first conductivity-type epitaxial pattern 220_1 and the second conductivity-type epitaxial pattern 220_2 may have different shapes along a crystallographically stable surface during the growth process. For example, the first conductivity-type epitaxial pattern 220_1, which may be an N-type, may have a cross-sectional surface having a hexagonal shape or various other polygonal shapes with gentle angles or an elliptical shape, and the second conductivity-type epitaxial pattern 220_2, which may be a P-type, may have a cross-sectional surface having a pentagonal shape or various other polygonal shapes.

In some example embodiments, the first conductivity-type epitaxial pattern 220_1 and the second conductivity-type epitaxial pattern 220_2 may be formed together with the source/drain patterns 120 of the first device 101 illustrated in FIGS. 2 to 4. For example, the first conductivity-type epitaxial pattern 220_1 may include the same material as a material of the source/drain patterns 120. For example, the second conductivity-type epitaxial pattern 220_2 may include the same material as a material of the source/drain patterns 120.

The first interlayer insulating layer 171 may be disposed on the first surface of the substrate 110 and may cover the first conductivity-type epitaxial pattern 220_1 and the second conductivity-type epitaxial pattern 220_2. The second interlayer insulating layer 173 may be disposed on the first interlayer insulating layer 171. The third interlayer insulating layer 175 may be disposed on the second interlayer insulating layer 173. The fourth interlayer insulating layer 177 may be disposed on the third interlayer insulating layer 175.

The first intermediate insulating layer 162 may be disposed on the first interlayer insulating layer 171. The first intermediate insulating layer 162 may include a first opening 251 extending in the second direction (e.g., Y-direction) intersecting the first direction in the second device 201. For example, the first opening 251 may be formed on a region between the first conductivity-type epitaxial pattern 220_1 and the second conductivity-type epitaxial pattern 220_2 arranged in the first direction (e.g., X-direction). The first opening 251 may be formed on an upper portion of the region between the first conductivity-type epitaxial pattern 220_1 and the second conductivity-type epitaxial pattern 220_2 arranged in the first direction (e.g., X-direction). The first opening 251 may be formed on a corresponding region between two adjacent spacer layers 234. The first opening 251 may overlap a portion, in which the first conductivity-type impurity region 210_1 and the second conductivity-type impurity region 210_2 are in contact with each other, in the third direction (e.g., Z-direction) intersecting each of the first direction (e.g., X-direction) and the second direction (e.g., Y-direction). In FIG. 5, as for the first opening 251, a width of an upper portion thereof in the first direction (e.g., X-direction) may be the same as a width of a lower portion thereof in the first direction, but an example embodiment thereof is not limited thereto. For example, the width in the first direction of an upper portion of the first opening 251 may be longer or shorter than the width in the first direction of a lower portion thereof. In this case, the width L_1 in the first direction (e.g., X-direction) of the first opening 251 may be defined as the average value of the width in the first direction of an upper portion of the first opening 251 and the width in the first direction of a lower portion of the first opening 251.

The central insulating layer CIL may be disposed between the first conductivity-type epitaxial pattern 220_1 and the second conductivity-type epitaxial pattern 220_2. The central insulating layer CIL may extend in the second direction (e.g., Y-direction). The central insulating layer CIL may fill the first opening 251. The central insulating layer CIL may overlap the second interlayer insulating layer 173 in the first direction (e.g., X-direction). The width W_2 in the first direction (e.g., X-direction) of the central insulating layer CIL on a lower end of the first opening 251 may be longer than the width L_1 in the first direction of the first opening 251. Also, the width W_2 in the first direction (e.g., X-direction) of the central insulating layer CIL on a lower end of the first opening 251 may be longer than the width W_1 in the first direction of the gate electrode 136 illustrated in FIG. 2.

The central insulating layer CIL may be in contact with the conductivity-type impurity region (e.g., the first conductivity-type impurity region 210_1 and the second conductivity-type impurity region 210_2). The central insulating layer CIL may be in contact with the first conductivity-type epitaxial pattern 220_1 and the second conductivity-type epitaxial pattern 220_2. The central insulating layer CIL may be in contact with the first intermediate insulating layer 162. The central insulating layer CIL may be formed of the same material as a material of the second interlayer insulating layer 173. For example, the central insulating layer CIL may include at least one from among an oxide, a nitride, and a combination thereof. The central insulating layer CIL and the first intermediate insulating layer 162 may be formed of different materials from each other. However, an example embodiment thereof is not limited thereto, and the central insulating layer CIL and the first intermediate insulating layer 162 may be formed of the same or similar material as each other.

In some example embodiments, the region filled with the central insulating layer CIL may be a region of a sacrificial gate structure formed together with the gate structure 130 of the first device 101 in FIG. 2. The sacrificial gate structure may be replaced with the central insulating layer CIL. Accordingly, the central insulating layer CIL may isolate the first conductivity-type epitaxial pattern 220_1 and the second conductivity-type epitaxial pattern 220_2 from each other.

In some example embodiments, the central insulating layer CIL may be formed together with the first device 101 illustrated in FIGS. 2 to 4. For example, the central insulating layer CIL may overlap the entire gate electrode 136 of the first device 101 in the first direction (e.g., X-direction) and the second direction (e.g., Y-direction).

In some example embodiments, the second device 201 may further include spacer layers 234. In example embodiments, “spacer layers” refers only to spacer layers 234 formed on the second device 201, and does not refer to the other same or similar elements. For example, referring to FIG. 2, the spacer layers formed on the first device 101 may be referred to as gate spacer layers 134 or isolation spacer layers 138, respectively. The spacer layers 234 may be formed simultaneously with the gate spacer layers 134 and/or the isolation spacer layers 138 illustrated in FIG. 2.

The spacer layers 234 may be disposed on a side surface of the first interlayer insulating layer 171 in the first direction (e.g., X-direction). Each of the spacer layers 234 may extend in the second direction (e.g., Y-direction). The spacer layers 234 may be disposed on one side surface of the contact structure 240. The spacer layers 234 may be in contact with the first intermediate insulating layer 162. The spacer layers 234 are disposed on the first conductivity-type epitaxial pattern 220_1 and the second conductivity-type epitaxial pattern 220_2, and may be in contact with the first conductivity-type epitaxial pattern 220_1 and the second conductivity-type epitaxial pattern 220_2. The central insulating layer CIL may be in contact with each of the spacer layers 234 between the adjacent spacer layers 234. Here, the width W_2 in the first direction (e.g., X-direction) between the adjacent spacer layers 234 in contact with the central insulating layer CIL may be defined. That is, the width W_2 in the first direction (e.g., X-direction) of the central insulating layer CIL between the spacer layers 234 may be longer than the width L_1 in the first direction of the first opening 251.

Contact structures 240 may be disposed on conductivity impurity regions 210_1 and 220_1 and may be connected to first conductivity-type epitaxial pattern 220_1 and the second conductivity-type epitaxial pattern 220_2. For example, one of the contact structures 240 may be in contact with the first conductivity-type epitaxial pattern 220_1, and the other contact structure 240 may be in contact with the second conductivity-type epitaxial pattern 220_2. The contact structures 240 may be connected to the first conductivity-type epitaxial pattern 220_1 and the second conductivity-type epitaxial pattern 220_2 and may apply an electrical signal. For example, the contact structures 240 may penetrate the second interlayer insulating layer 173 and may be in contact with the first conductivity-type epitaxial pattern 220_1 and the second conductivity-type epitaxial pattern 220_2, respectively.

The contact structures 240 may be disposed to have a length longer than the first conductivity-type epitaxial pattern 220_1 and the second conductivity-type epitaxial pattern 220_2 in the second direction (e.g., Y-direction). The contact structures 240 may have an inclined side surface in which a width of a lower portion thereof is narrower than a width of an upper portion thereof depending on an aspect ratio, but an example embodiment thereof is not limited thereto. For example, the contact structures 240 may be recessed (e.g., protrude) into the first conductivity-type epitaxial pattern 220_1 and the second conductivity-type epitaxial pattern 220_2 and may be in contact with the first conductivity-type epitaxial pattern 220_1 and the second conductivity-type epitaxial pattern 220_2, but an example embodiment thereof is not limited thereto. For example, the contact structures 240 may not be recessed (e.g., protrude) into the first conductivity-type epitaxial pattern 220_1 and the second conductivity-type epitaxial pattern 220_2 and may be in contact with the upper surfaces of the first conductivity-type epitaxial pattern 220_1 and the second conductivity-type epitaxial pattern 220_2.

The upper surface of each of the contact structures 240 may be positioned at the same level as the upper surface of the second interlayer insulating layer 173 in the third direction (e.g., Z-direction), but an example embodiment thereof is not limited thereto. The upper surface of at least one of the contact structures 240 may be disposed at a level higher than a level of the upper surface of the isolation structure SS illustrated in FIG. 2 in the third direction (e.g., Z-direction). The upper surface of the contact structures 240 may be positioned at a level higher than a level of the spacer layers 234 in the third direction (e.g., Z-direction). Each of the contact structures 240 may include a conductive material 246, and a conductive barrier 244 surrounding a side surface and a lower surface of the conductive material 246. Each of the contact structures 240 may further include a metal silicide film 242 formed on the first conductivity-type epitaxial pattern 220_1 and the second conductivity-type epitaxial pattern 220_2 to improve contact resistance.

The second device 201 may further include a second intermediate insulating layer 164 and a third intermediate insulating layer 166. The second device 201 may further include an upper interconnection structure 150_U and a lower interconnection structure 150_B. The upper interconnection structure 150_U may be disposed on the contact structures 240. The upper interconnection structure 150_U may include a plurality of second upper vias V2_U and a plurality of second upper metal lines M2_U. The lower interconnection structure 150_B may be disposed on the second surface of the substrate 110. The lower interconnection structure 150_B may include a plurality of second lower vias V2_U and a plurality of second lower metal lines M2_B. The plurality of second upper vias V2_U may penetrate at least the third interlayer insulating layer 175 and may be connected to the first conductivity-type epitaxial pattern 220_1 and the second conductivity-type epitaxial pattern 220_2. For example, the second upper via V2_U may penetrate the third interlayer insulating layer 175 and the second intermediate insulating layer 164 and may be in contact with the first conductivity-type epitaxial pattern 220_1 and the second conductivity-type epitaxial pattern 220_2.

The second device 201 may include power transfer structures for supplying power to each transistor cell from the second surface of the substrate 110. For example, the power transfer structures may include a plurality of through-buried structures 262 arranged in the second direction (e.g., Y-direction) and a plurality of third through-insulating layers 264 surrounding bottom surfaces and side surfaces of the plurality of through-buried structures 262.

For example, a third through-buried structure 262 may extend from the upper interconnection structure 150_U in the third direction (e.g., Z-direction), may penetrate the substrate 110, and may be connected to the lower interconnection structure 150_B. The third through-buried structure 262 may penetrate the second interlayer insulating layer 173, the first intermediate insulating layer 162, the first interlayer insulating layer 171, the element isolation layer 180, the substrate 110, and the insulating protective layer 191, and may be connected to the lower interconnection structure 150_B. The plurality of third through-buried structures 262 may be electrically connected to the first conductivity-type epitaxial pattern 220_1 and the second conductivity-type epitaxial pattern 220_2 by the second upper metal line M2_U, which may be a power line of the upper interconnection structure 150_U. The plurality of third through-buried structures 262 may be electrically connected to the first conductivity-type epitaxial pattern 220_1 and the second conductivity-type epitaxial pattern 220_2 by the second lower metal line M2_B. For example, the third through-buried structure 262 may be electrically connected to the first conductivity-type epitaxial pattern 220_1 by the second upper metal line M2_U. For example, the third through-buried structure 262 may be electrically connected to the second conductivity-type epitaxial pattern 220_2 by the second upper metal line M2_U. The third through-buried structure 262 may receive power from the second lower metal line M2_B and may supply power to the first conductivity-type epitaxial pattern 220_1 and the second conductivity-type epitaxial pattern 220_2 of the second device 201.

In some example embodiments, an insulating protective layer (or etching stop layer) 191 may be disposed on the second surface (or a lower surface) of the substrate 110 formed on the second device 201. The insulating protective layer 191 may surround a contact region of a through-buried structure 262 protruding from the second surface of the substrate 110. A lower interconnection structure 150_B may be disposed on the insulating protective layer 191. The lower interconnection structure 150_B may include a plurality of second lower vias V2_B and a plurality of second lower metal lines M2_B buried in the lower interlayer insulating layer 170_B.

In the example embodiments described with reference to FIGS. 2 to 9, the substrate 110 of the first device 101 and the second device 201 may be completely removed other than a portion on which active patterns (e.g., the first active pattern AP_1 and the second active pattern AP_2) are formed.

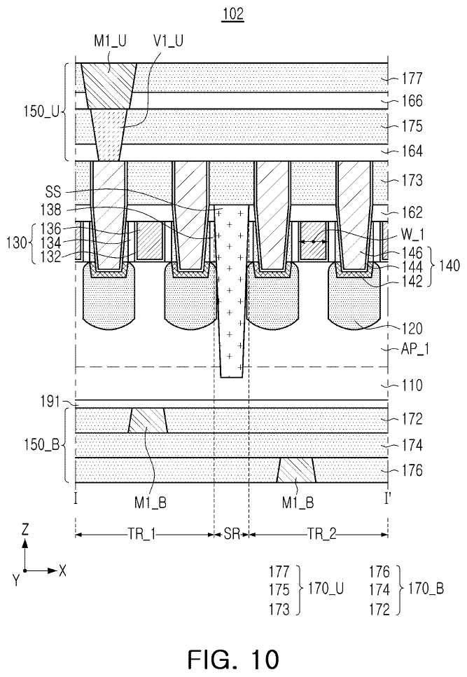

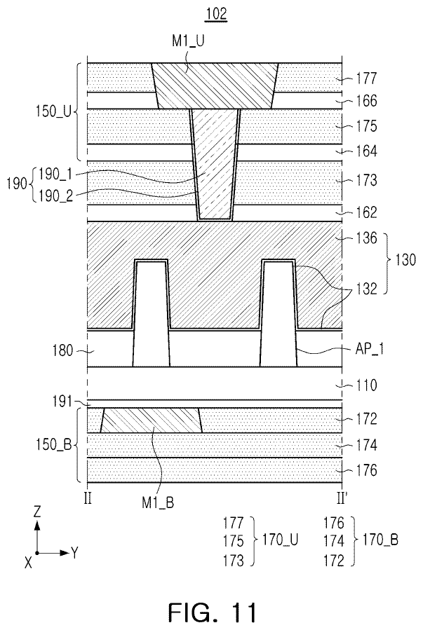

FIG. 10 is a cross-sectional diagram illustrating a first device of a semiconductor device taken along a line I-I′ in FIG. 1 according to an example embodiment. FIG. 11 is a cross-sectional diagram illustrating a first device of a semiconductor device taken along a line II-II′ in FIG. 1 according to an example embodiment. For ease of description, repeated descriptions of elements the same as or similar to elements of the example embodiments described with reference to FIGS. 1 to 4 may not be provided.

Referring to FIGS. 10 and 11, cross-sectional surfaces of a first device 102 including a FinFET in which a gate structure 130 surrounds three surfaces of a first active pattern AP_1 (e.g., an upper surface and side surfaces in the second direction (e.g., Y-direction) of the first active pattern AP_1) are illustrated. Differently from the example embodiment in FIG. 2, the first device 101 of the semiconductor device 10 may not include a plurality of semiconductor patterns. In this case, the first device 101 may include a portion of the first active pattern AP_1 and a channel region surrounded by the gate structure 130.

The isolation structure SS may be recessed (e.g., protrude) into the gate structure 130 and the channel region, and a lower end of the isolation structure SS may be positioned below a lower end of the first active pattern AP_1. Side surfaces of the isolation structure SS may not be in contact with side surfaces of adjacent source/drain patterns 120. In another example embodiment, side surfaces of the isolation structure SS may be in contact with side surfaces of adjacent source/drain patterns 120. A lower portion of the isolation structure SS may have a flat surface or a curved shape, or the like, but an example embodiment thereof is not limited thereto, and may have various shapes.

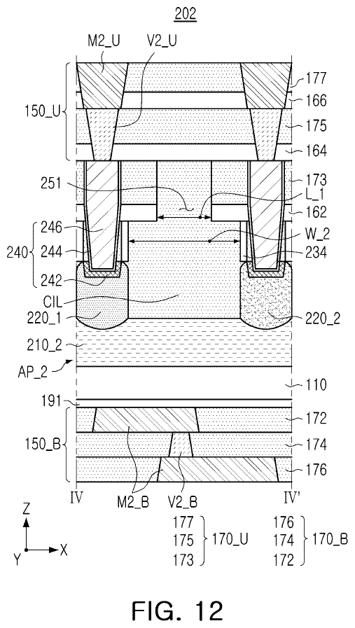

FIG. 12 is a cross-sectional diagram illustrating a second device of a semiconductor device taken along a line IV-IV′ in FIG. 1 according to an example embodiment. For ease of description, repeated description of the same or similar elements as the elements of the example embodiments described with reference to FIGS. 1 to 9 may not be provided. Referring to FIG. 12, the second active pattern AP_2 of the second device 202 may include only a second conductivity-type impurity region 210_2 extending in the first direction (e.g., X-direction). The second conductivity-type impurity region 210_2 may be, for example, a P-type region. When the second conductivity-type impurity region 210_2 is a P-type region, the first conductivity-type epitaxial pattern 220_1 may be an N-type epitaxial pattern, and the second conductivity-type epitaxial pattern 220_2 may be a P-type epitaxial pattern. In this case, the second conductivity-type impurity region 210_2 and the first conductivity-type epitaxial pattern 220_1 may form a p-n bonding structure. When the second conductivity-type impurity region 210_2 is an N-type region, the first conductivity-type epitaxial pattern 220_1 may be a P-type epitaxial pattern, and the second conductivity-type epitaxial pattern 220_2 may be an N-type epitaxial pattern. In this case, the second conductivity-type impurity region 210_2 and the first conductivity-type epitaxial pattern 220_1 may form a p-n bonding structure. However, an example embodiment thereof is not limited thereto, and various p-n bonding structures may be formed between the second conductivity-type impurity region 210_2 and the first conductivity-type epitaxial pattern 220_1 and the second conductivity-type epitaxial pattern 220_2 depending on the doping type. Differently from the illustrated example, the second active pattern AP_2 may include only the first conductivity-type impurity region 210_1 extending in the first direction. Accordingly, the second device 202 may include a diode, and may also be implemented as various electronic devices or semiconductor elements including a p-n bonding structure, a p-n-p bonding structure, an n-p-n bonding structure, or the like.

For example, when the second conductivity-type impurity region 210_2 and the first conductivity-type epitaxial pattern 220_1 form a p-n bonding structure, the second conductivity-type epitaxial pattern 220_2 may function as an electrical path for the second conductivity-type impurity region 210_2. For example, the second conductivity-type impurity region 210_2 may receive an electrical signal from the upper interconnection structure 150_U through the second conductivity-type epitaxial pattern 220_2 and the contact structures 240.

In some example embodiments, the second conductivity-type impurity region 210_2 may be a P-type region, the first conductivity-type epitaxial pattern 220_1 may be an N-type epitaxial pattern, and the second conductivity-type epitaxial pattern 220_2 may be a P-type epitaxial pattern. In this case, the first conductivity-type epitaxial pattern 220_1 may be a cathode of a diode, and the second conductivity-type impurity region 210_2 and the second conductivity-type epitaxial pattern 220_2 may be an anode of a diode.

In some example embodiments, referring to FIGS. 6 and 7 together, the second device 202 may include a third through-buried structure 262 and a third through-insulating layer 264 formed in the second direction (e.g., Y-direction). The third through-buried structure 262 and the third through-insulating layer 264 of the second device 202 may have the same or similar structure as that of the third through-buried structure 262 and the third through-insulating layer 264 of the second device 201 according to an example embodiment described with reference to FIGS. 5 to 9, and may perform the same or similar function.

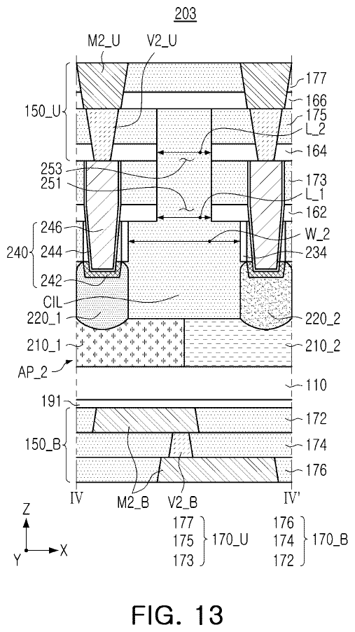

FIG. 13 is a cross-sectional diagram illustrating a second device of a semiconductor device taken along a line IV-IV′ in FIG. 1 according to an example embodiment. For ease of description, repeated description of the same or similar elements as the elements of the example embodiments described with reference to FIGS. 1 to 12 may not be provided. Referring to FIG. 13, the second device 203 may further include a first opening 251 formed in a first intermediate insulating layer 162, and a second opening 253 formed in a second intermediate insulating layer 164. The second opening 253 may extend in the second direction (e.g., Y-direction) intersecting the first direction (e.g., X-direction). The second opening 253 may overlap at least a portion of the first opening 251 in the third direction (e.g., Z-direction) intersecting the first direction and the second direction. The second opening 253 may be formed between a first conductivity-type epitaxial pattern 220_1 and a second conductivity-type epitaxial pattern 220_2 arranged in the first direction (e.g., X-direction). The second opening 253 may be formed on a corresponding region between two adjacent spacer layers 234. The second opening 253 may be formed to overlap a portion in contact with the first conductivity-type impurity region 210_1 and the second conductivity-type impurity region 210_2 in the third direction (e.g., Z-direction). In FIG. 13, as for the first opening 251 and the second opening 253, a width in the first direction (e.g., X-direction) of an upper portion thereof and a width in the first direction of a lower portion thereof may be the same, but an example embodiment thereof is not limited thereto. For example, as for the first opening 251 and the second opening 253, a width of an upper portion thereof in the first direction may be longer or shorter than a width of a lower portion thereof in the first direction. In this case, widths L_1 and L_2 in the first direction (e.g., X-direction) of the first opening 251 and the second opening 253 may be defined as average values of widths in the first direction of an upper portion of each of the first opening 251 and the second opening 253 and widths in the first direction of a lower portion of each of the first opening 251 and second opening 253, respectively.

In some example embodiments, the width L_2 in the first direction (e.g., X-direction) of the second opening 253 may be the same as the width L_1 in the first direction of the first opening 251. The width L_2 in the first direction (e.g., X-direction) of the second opening 253 may be longer or shorter than the width L_1 in the first direction of the first opening 251.

In some example embodiments, similarly to the second device 201 described with reference to FIGS. 5 to 9, the second device 203 may be implemented as a diode having a p-n bonding structure, and may also be implemented as various electronic devices or semiconductor devices requiring a p-n bonding structure.

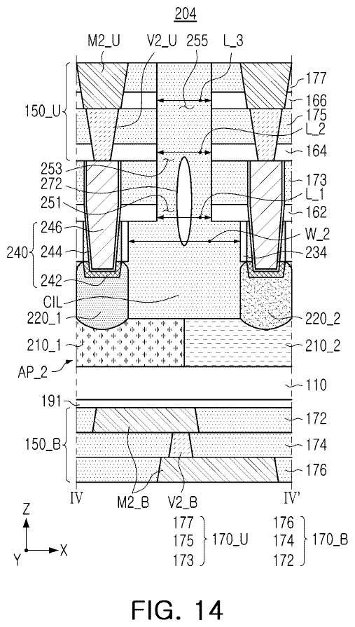

FIG. 14 is a cross-sectional diagram illustrating a second device of a semiconductor device taken along a line IV-IV′ in FIG. 1 according to an example embodiment. For ease of description, repeated description of the same or similar elements as the elements of the example embodiments described with reference to FIGS. 1 to 13 may not be provided. Referring to FIG. 14, the second device 204 may further include a first opening 251 formed in a first intermediate insulating layer 162, a second opening 253 formed in a second intermediate insulating layer 164, and a third opening 255 formed in a third intermediate insulating layer 166. The third opening 255 may extend in the second direction (e.g., Y-direction) intersecting the first direction (e.g., X-direction). The third opening 255 may overlap at least a portion of the first opening 251 and/or the second opening 253 in the third direction (e.g., Z-direction) intersecting the first and second directions. The third opening 255 may be formed between the first conductivity-type epitaxial pattern 220_1 and the second conductivity-type epitaxial pattern 220_2 arranged in the first direction (e.g., X-direction). The third opening 255 may be formed on a corresponding region between two adjacent spacer layers 234. The third opening 255 may be formed to overlap a portion in contact with the first conductivity-type impurity region 210_1 and the second conductivity-type impurity region 210_2 in the third direction (e.g., Z-direction). In FIG. 14, in each of the first opening 251, the second opening 253, and the third opening 255, a width in the first direction (e.g., X-direction) of an upper portion thereof may be the same as a width in the first direction of a lower portion thereof, but an example embodiment thereof is not limited thereto. For example, in each of the first opening 251, the second opening 253 and the third opening 255, a width in the first direction of an upper portion thereof may be longer or shorter than a width in the first direction of a lower portion thereof. In this case, the widths L_1, L_2 and L_3 in the first direction (e.g., X-direction) of the first opening 251, the second opening 253 and the third opening 255 may be defined as average values of the widths in the first direction of upper portions of the first opening 251, the second opening 253 and the third opening 255 and the widths in the first direction of lower portions of the first opening 251, the second opening 253 and the third opening 255, respectively.

In some example embodiments, the width L_3 in the first direction (e.g., X-direction) of the third opening 255 may be the same as the widths L_1, L_2 in the first direction of the first opening 251 and/or the second opening 253. The width L_3 in the first direction (e.g., X-direction) of the third opening 255 may be longer or shorter than the widths L_1, L_2 in the first direction of the first opening 251 and/or the second opening 253.

In some example embodiments, the central insulating layer CIL may further include a void 272 formed in the central insulating layer CIL. The void 272 may overlap the first opening 251 in the first direction (e.g., X-direction). The void 272 may overlap the second opening 253 in the first direction. The void 272 may be formed at a level lower than a level of an upper portion of the second opening 253. However, the void 272 may also be formed to the same level as an upper portion of the second opening 253. In the illustrated example embodiment, the void 272 may have an oval shape, but an example embodiment thereof is not limited thereto, and the void 272 may have a shape such as a circular shape. The example embodiments of the void 272 described above may also be applied to the second devices 201, 202, and 203 according to the example embodiments described with reference to FIGS. 5 to 13.

In some example embodiments, similarly to the second device 201 described with reference to FIGS. 5 to 9, the second device 204 may include a diode having a p-n bonding structure, and may also be implemented as various electronic devices or semiconductor elements including a p-n bonding structure, a p-n-p bonding structure, an n-p-n bonding structure, or the like.

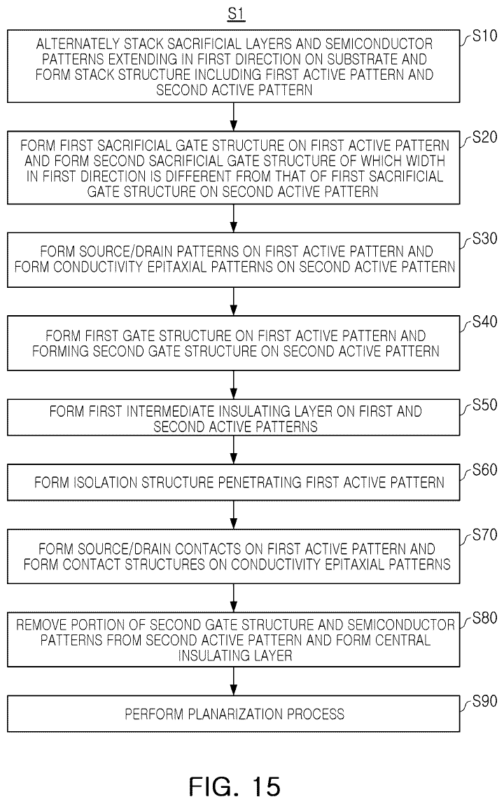

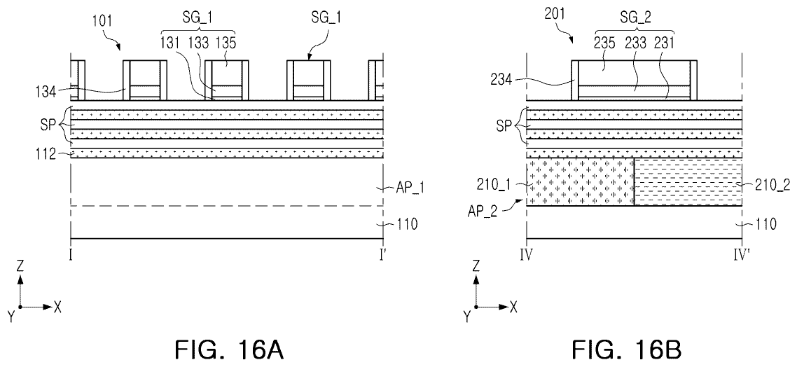

FIG. 15 is a flowchart illustrating a method of manufacturing a semiconductor device according to some example embodiments. FIGS. 16A to 33B are intermediate process diagrams illustrating a method of manufacturing a semiconductor device according to some example embodiments. For ease of description, repeated descriptions of elements the same as or similar to the elements of the example embodiments described with reference to FIGS. 1 to 14 may not be provided. Referring to FIGS. 15 and 16A-16B, a method S1 of manufacturing a semiconductor device according to some example embodiments may include alternately stacking sacrificial layers 112 and semiconductor patterns SP extending in the first direction (e.g., X-direction) on a substrate 110 in a direction perpendicular to the first direction (e.g., Z-direction) and forming an active structure including a first active pattern AP_1 and a second active pattern AP_2. Here, a first device 101 of the semiconductor device and a second device 201 spaced apart from the first device 101 may be formed together.

The sacrificial layers 112 may be replaced with the gate dielectric layer 132 and the gate electrode 136 through a subsequent process as in FIG. 2. The sacrificial layers 112 may be formed of a material having etch selectivity with respect to the semiconductor patterns SP. The semiconductor patterns SP may be formed of a material different from a material of the sacrificial layers 112. For example, the sacrificial layers 112 and the semiconductor patterns SP may include a semiconductor material including at least one from among silicon (Si), silicon germanium (SiGe), and germanium (Ge), and may include different materials and may or may not include impurities. For example, the sacrificial layers 112 may include silicon germanium (SiGe), and the semiconductor patterns SP may include silicon (Si).

The sacrificial layers 112 and the semiconductor patterns SP may be formed by performing an epitaxial growth process using the substrate 110 as a seed. The number of layers of layers of the semiconductor patterns SP alternately stacked with the sacrificial layers 112 may be varied in example embodiments.

Thereafter, by removing a stack structure of the sacrificial layers 112 and the semiconductor patterns SP and a portion of the substrate 110, active structures may be formed. The active structures may include the sacrificial layers 112 and the semiconductor patterns SP alternately stacked. The active structures may further include active patterns (e.g., the first active pattern AP_1 and the second active pattern AP_2) protruding to the upper surface of the substrate 110 by removing a portion of the substrate 110. The active patterns (e.g., the first active pattern AP_1 and the second active pattern AP_2) may be formed in a line shape extending in the first direction (e.g., X-direction) and may be spaced apart from each other in the second direction (e.g., Y-direction) intersecting the first direction.

In some example embodiments, the conductivity-type impurity regions (e.g., the first conductivity-type impurity region 210_1 and the second conductivity-type impurity region 210_2) may be formed preferentially on the substrate 110 of the second device 201 before forming the semiconductor patterns SP. In some example embodiments, the conductivity-type impurity regions (e.g., the first conductivity-type impurity region 210_1 and the second conductivity-type impurity region 210_2) may be formed on the substrate 110 of the second device 201 after forming the active structure. The conductivity-type impurity regions (e.g., the first conductivity-type impurity region 210_1 and the second conductivity-type impurity region 210_2) may be formed through a selective ion implantation process, or the like.

An insulating material may be filled in the region from which a portion of the substrate 110 is removed, and active patterns (e.g., the first active pattern AP_1 and the second active pattern AP_2) may be recessed to protrude, thereby forming element isolation layers (e.g., element isolation layer 180 in FIG. 3). An upper surface of the element isolation layers may be formed at a level lower than a level of the upper surface of the active patterns (e.g., the first active pattern AP_1 and the second active pattern AP_2).

Subsequently, forming sacrificial gate structures (e.g., the first sacrificial gate structure SG_1 and the second sacrificial gate structure SG_2) on the active structures may be included. For example, the method S1 may include forming a first sacrificial gate structure SG_1 on a first active pattern AP_1 and forming a second sacrificial gate structure SG_2 on a second active pattern AP_2 (operation S20). Here, a width in the first direction (e.g., X-direction) of the second sacrificial gate structure SG_2 may be different from a width in the first direction of the first sacrificial gate structure SG_1. Specifically, a width W_2 in the first direction (e.g., X-direction) of the second sacrificial gate structure SG_2 may be larger than a width W_1 in the first direction of the first sacrificial gate structure SG_1.

In some example embodiments, the sacrificial gate structures (e.g., the first sacrificial gate structure SG_1 and the second sacrificial gate structure SG_2) may be sacrificial structures formed in a region in which the gate dielectric layer 132 and the gate electrode 136 are disposed in an upper portion of the semiconductor patterns SP through a subsequent process as illustrated in FIG. 2. The sacrificial gate structures (e.g., the first sacrificial gate structure SG_1 and the second sacrificial gate structure SG_2) may include first sacrificial gate layers 131 and 231, second sacrificial gate layers 133 and 233, and gate mask pattern layers 135 and 235 stacked in order. The first sacrificial gate layers 131 and 231 and the second sacrificial gate layers 133 and 233 may be patterned using the gate mask pattern layers 135 and 235. The first sacrificial gate layers 131 and 231 and the second sacrificial gate layers 133 and 233 may be insulating layers and conductive layers, respectively, but an example embodiment thereof is not limited thereto. The first sacrificial gate layers 131 and 231 and the second sacrificial gate layers 133 and 233 may be formed as an integrated layer. For example, the first sacrificial gate layers 131 and 231 may include silicon oxide, and the second sacrificial gate layers 133 and 233 may include polysilicon. The gate mask pattern layers 135 and 235 may include silicon oxide and/or silicon nitride. The sacrificial gate structures (e.g., the first sacrificial gate structure SG_1 and the second sacrificial gate structure SG_2) may have a line shape extending in one direction, intersecting the active structures. For example, the sacrificial gate structures (e.g., the first sacrificial gate structure SG_1 and the second sacrificial gate structure SG_2) may extend in the second direction (e.g., Y-direction) and may be spaced apart from each other in the first direction (e.g., X-direction).

Gate spacer layers 134 and spacer layers 234 may be formed on both sidewalls of the sacrificial gate structures (e.g., the first sacrificial gate structure SG_1 and the second sacrificial gate structure SG_2), respectively. The gate spacer layers 134 and the spacer layers 234 may be formed by forming a film with a uniform thickness along an upper surface and a side surface of sacrificial gate structures (e.g., the first sacrificial gate structure SG_1 and the second sacrificial gate structure SG_2) and active structures, and anisotropically etching. For example, the gate spacer layers 134 and the spacer layers 234 may include at least one from among oxide, nitride, oxynitride, and silicon nitride materials

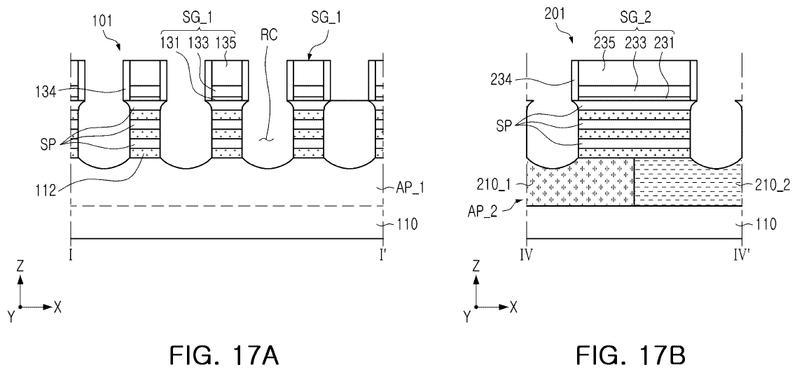

Referring to FIGS. 15 and 17A-17B, the method S1 may include forming a recess region RC by removing exposed portions of the sacrificial layers 112 and semiconductor patterns SP between the sacrificial gate structures (e.g., the first sacrificial gate structure SG_1 and the second sacrificial gate structure SG_2). The exposed portions of the sacrificial layers 112 and the semiconductor patterns SP may be removed using the sacrificial gate structures (e.g., the first sacrificial gate structure SG_1 and the second sacrificial gate structure SG_2), the gate spacer layers 134 and the spacer layers 234 as masks. Accordingly, the semiconductor patterns SP may have a limited length in the first direction (e.g., X-direction)

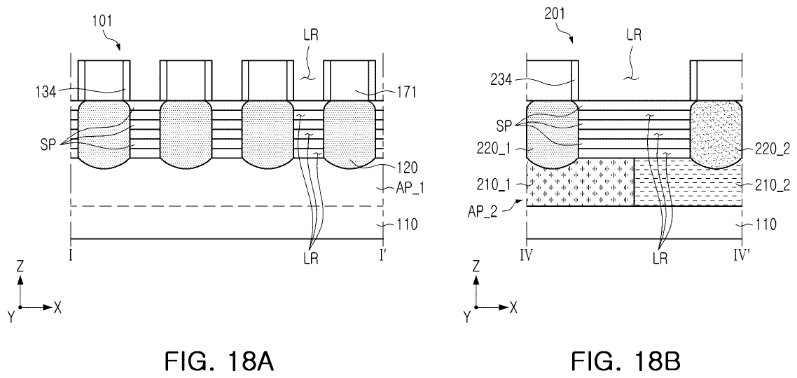

Referring to FIGS. 15 and 18A-18B, the method S1 may include forming source/drain patterns 120 on a first active pattern AP_1 and forming conductive epitaxial patterns (e.g., the first conductivity-type epitaxial pattern 220_1 and the second conductivity-type epitaxial pattern 220_2) on a second active pattern AP_2 on both sides of sacrificial gate structures (e.g., the first sacrificial gate structure SG_1 and the second sacrificial gate structure SG_2) (operation S30). The source/drain patterns 120 and the conductive epitaxial patterns (e.g., the first conductivity-type epitaxial pattern 220_1 and the second conductivity-type epitaxial pattern 220_2) may be formed by performing a selective epitaxial growth process. The source/drain patterns 120 and the conductive epitaxial patterns (e.g., the first conductivity-type epitaxial pattern 220_1 and the second conductivity-type epitaxial pattern 220_2) may be connected to the plurality of semiconductor patterns SP through a side surface thereof. The source/drain patterns 120 and the conductive epitaxial patterns (e.g., the first conductivity-type epitaxial pattern 220_1 and the second conductivity-type epitaxial pattern 220_2) may further include impurities by in-situ doping, and may also include a plurality of layers having different doping elements and/or doping concentrations.

Thereafter, the first interlayer insulating layer 171 may be formed, and the sacrificial layers 112 and the sacrificial gate structures (e.g., the first sacrificial gate structure SG_1 and the second sacrificial gate structure SG_2) may be removed. The first interlayer insulating layer 171 may be formed by performing a planarization process after forming an insulating layer covering the sacrificial gate structures (e.g., the first sacrificial gate structure SG_1 and the second sacrificial gate structure SG_2), the source/drain patterns 120, the first conductivity-type epitaxial pattern 220_1, and the second conductivity-type epitaxial pattern 220_2.

The sacrificial layers 112 and the sacrificial gate structures (e.g., the first sacrificial gate structure SG_1 and the second sacrificial gate structure SG_2) may be selectively removed with respect to the gate spacer layers 134, the spacer layers 234, the first interlayer insulating layer 171 and the semiconductor patterns SP. First, the sacrificial gate structures (e.g., the first sacrificial gate structure SG_1 and the second sacrificial gate structure SG_2) may be removed, and the sacrificial layers 112 may be removed, thereby forming lower gap regions LR. For example, when the sacrificial layers 112 include silicon germanium (SiGe) and the semiconductor patterns SP include silicon (Si), the sacrificial layers 112 may be selectively removed by performing a wet etching process using peracetic acid as an etchant. During the removal process, the source/drain patterns 120 and the first conductivity-type epitaxial pattern 220_1 and the second conductivity-type epitaxial pattern 220_2 may be protected by the first interlayer insulating layer 171.

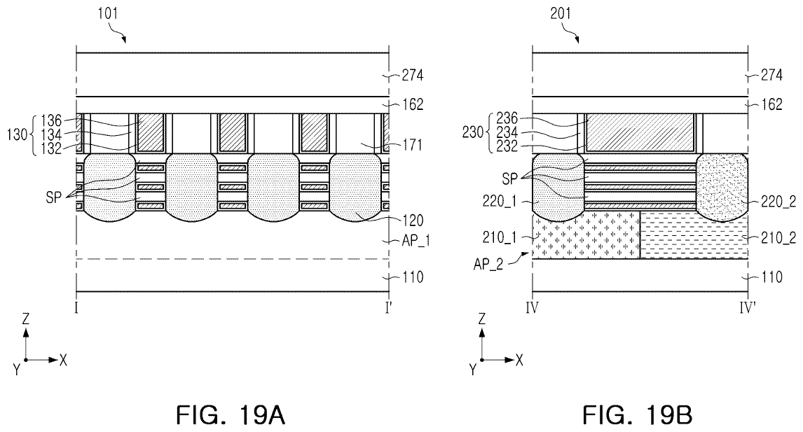

Referring to FIGS. 15 and 19A-19B, the method S1 may include forming a first gate structure (e.g., the gate structure 130) on a first active pattern AP_1 and forming a second gate structure 230 on a second active pattern AP_2 (operation S40). In some example embodiments, when forming the first gate structure (e.g., the gate structure 130), a gate electrode 136 extending in the second direction (e.g., Y-direction) intersecting the semiconductor patterns SP and surrounding the semiconductor patterns SP and the gate spacer layers 134 disposed on both sides of the gate electrode 136 may be formed. In some example embodiments, when forming the second gate structure 230, a sacrificial gate electrode 236 extending in the second direction, intersecting the semiconductor patterns SP and surrounding the semiconductor patterns SP and spacer layers 234 disposed on both sides of the sacrificial gate electrode 236 may be formed.

The gate dielectric layers (e.g., the gate dielectric layer 132 and the sacrificial gate dielectric layer 232) may be formed to conformally cover internal surfaces of the lower gap regions LR. The gate electrodes (e.g., the gate electrode 136 and the sacrificial gate electrode 236) may be formed to completely fill the lower gap regions LR. In some example embodiments, the second gate structure 230 may be a partial sacrificial gate structure removed in a subsequent process other than the spacer layers 234. For example, when a portion of the second gate structure 230 is removed, the sacrificial gate electrode 236 may be removed.

Subsequently, a first intermediate insulating layer 162 and a sacrificial interlayer insulating layer 274 may be formed (operation S50) on the gate structures (e.g., the gate structure 130 and the second gate structure 230). The sacrificial interlayer insulating layer 274 may be formed of a material different from a material of the first intermediate insulating layer 162. The sacrificial interlayer insulating layer 274 may be formed of the same material as a material of the first interlayer insulating layer 171. For example, the first intermediate insulating layer 162 may include TetraEthyl OrthoSilicate (TEOS).

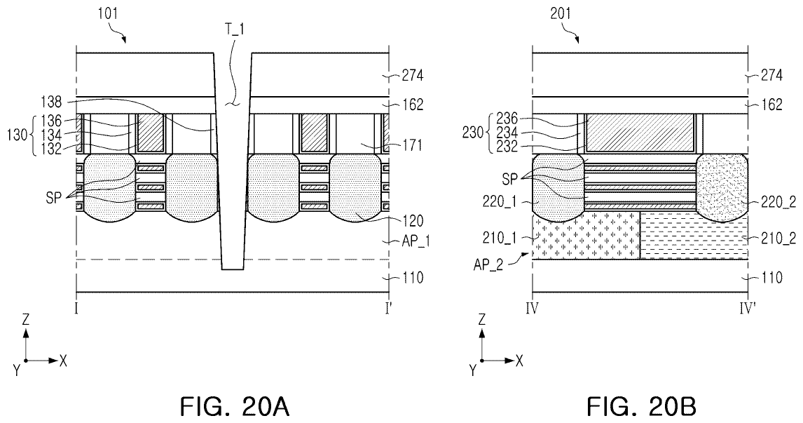

Referring to FIGS. 20A-20B, a first trench T_1 penetrating the first active pattern AP_1 and extending below a lower surface of the first active pattern AP_1 may be formed. Accordingly, a portion of the first gate structure (e.g., the gate structure 130) and a portion of the semiconductor patterns SP may be removed. The first trench T_1 may extend in the second direction (e.g., Y-direction) intersecting the first active pattern AP_1. The first trench T_1 may have an inclined side surface in which a width of a lower portion thereof is narrower than a width of an upper portion thereof depending on an aspect ratio. A lower portion of the first trench T_1 may have a flat surface and may have an outwardly curved or pointed shape facing the substrate 110. However, an example embodiment thereof is not limited thereto. A lower end of the first trench T_1 may be positioned at a level lower than a level of a lower end of the first active pattern AP_1. By forming the first trench T_1, isolation spacer layers 138 may be clearly defined.

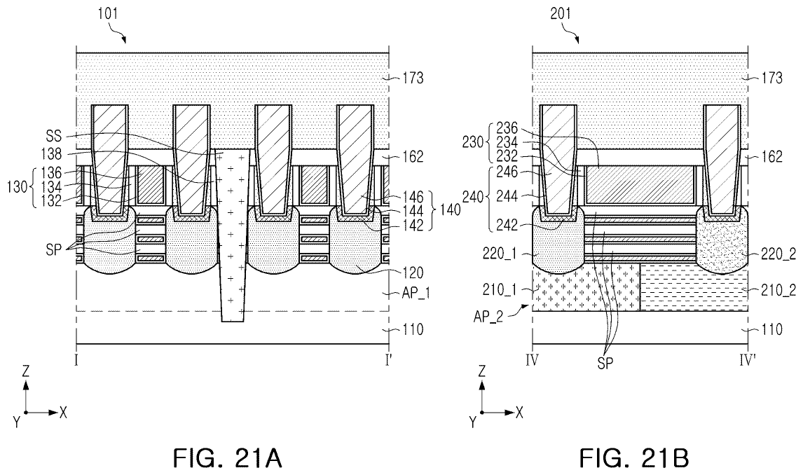

Referring to FIGS. 15 and 21A-21B, the method S1 may include forming an isolation structure SS penetrating the first active pattern AP_1 (operation S60), and forming source/drain contacts 140 on the first active pattern AP_1 and forming contact structures 240 on the conductive epitaxial patterns (e.g., the first conductivity-type epitaxial pattern 220_1 and the second conductivity-type epitaxial pattern 220_2) (operation S70).

The isolation structure SS may be formed by filling the first trench T_1. The isolation structure SS may include a silicon nitride series material. The isolation structure SS may be formed of the same material as a material of the first intermediate insulating layer 162. The isolation structure SS may be filled, and a planarization process of removing a portion of the isolation structure SS and the sacrificial interlayer insulating layer 274 may be performed. Here, the upper surface of the isolation structure SS may be positioned at the same level as the upper surface of the first intermediate insulating layer 162.

Thereafter, the source/drain contacts 140 may be formed on the source/drain patterns 120 of the first active pattern AP_1, and the contact structures 240 may be formed on the first conductivity-type epitaxial pattern 220_1 and the second conductivity-type epitaxial pattern 220_2 of the second active pattern AP_2. The upper surface of the source/drain contacts 140, the first conductivity-type epitaxial pattern 220_1, and the second conductivity-type epitaxial pattern 220_2 may be formed to be positioned at a level higher than a level of the upper surface of the first intermediate insulating layer 162. The upper surfaces of the source/drain contacts 140, the first conductivity-type epitaxial pattern 220_1, and the second conductivity-type epitaxial pattern 220_2 may be formed to be positioned at a level higher than a level of the upper surface of the isolation structure SS.

Thereafter, a second interlayer insulating layer 173 covering the isolation structure SS, the first intermediate insulating layer 162, the source/drain contacts 140, the first conductivity-type epitaxial pattern 220_1, and the second conductivity-type epitaxial pattern 220_2 may be formed.

Referring to FIG. 15 and FIGS. 22A to 26B, the method S1 may further include removing a portion of the second gate structure 230 and the semiconductor patterns SP from the second active pattern AP_2 and forming a central insulating layer CIL (operation S80) and performing a planarization process (operation S90), which will be described in detail in the illustrated order below.

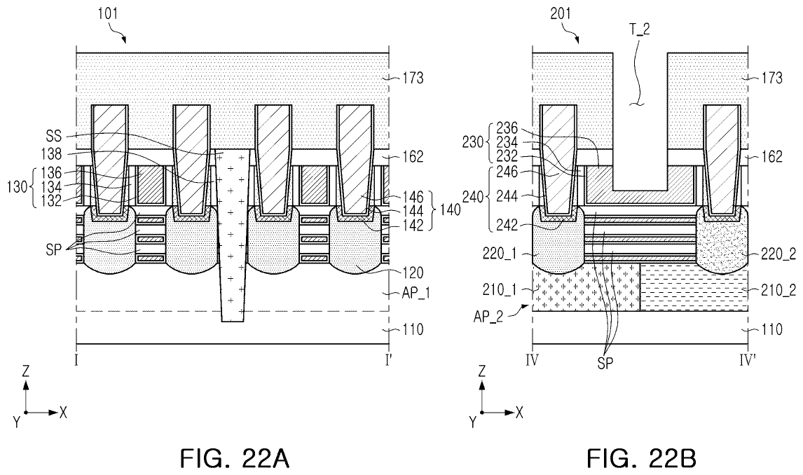

Referring to FIGS. 22A-22B, by removing a portion of the second interlayer insulating layer 173, the first intermediate insulating layer 162 on the second active pattern AP_2, and the second gate structure 230, a second trench T_2 may be formed. The second trench T_2 may be formed to penetrate the second interlayer insulating layer 173, the first intermediate insulating layer 162, and to be recessed (e.g., penetrate) into at least a portion of the second gate structure 230. A lower surface of the second trench T_2 may be formed at a level higher than a level of a lower surface of the sacrificial gate electrode 236 and may be formed at a level lower than a level of an upper surface of the sacrificial gate electrode 236. According to some embodiments, the second trench T_2 may have a tapered shape in which a width in the first direction (e.g., X-direction) decreases toward the substrate 110. The second trench T_2 may be formed through a dry etching process.

As the second trench T_2 is formed, an opening (e.g., the first opening 251 in FIG. 5) may be formed on the first intermediate insulating layer 162. The opening may be formed between the first conductivity-type impurity region 210_1 and the second conductivity-type impurity region 210_2 in the first direction (e.g., X-direction). The opening may be formed between the first conductivity-type epitaxial pattern 220_1 and the second conductivity-type epitaxial pattern 220_2 in the first direction. The opening may overlap a portion, in which the first conductivity-type impurity region 210_1 and the second conductivity-type impurity region 210_2 are in contact with each other in the first direction, in the first direction and in a third direction (e.g., Z-direction) perpendicular to the first direction. When the second trench T_2 has a tapered shape, the width of an upper portion of the opening in the first direction may be smaller than the width of a lower portion of the opening in the first direction.

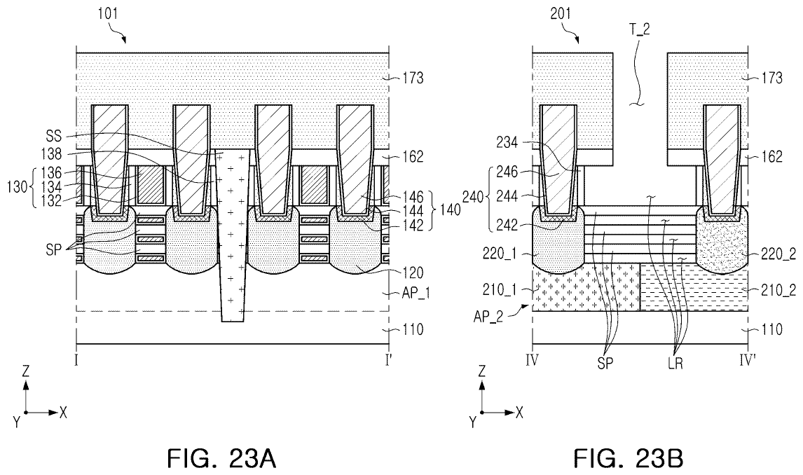

Referring to FIGS. 23A-23B, by removing the sacrificial gate dielectric layer 232 and the sacrificial gate electrode 236, the lower gap regions LR may be further formed. In this case, the spacer layers 234 may not be removed. The sacrificial gate dielectric layer 232 and the sacrificial gate electrode 236 may be removed through a wet etching process. In this case, the sacrificial gate dielectric layer 232 and the sacrificial gate electrode 236 may not be completely removed and may remain as residues on the conductivity-type impurity region (e.g., the first conductivity-type impurity region 210_1 and the second conductivity-type impurity region 210_2) or the conductive epitaxial patterns (e.g., the first conductivity-type epitaxial pattern 220_1 and the second conductivity-type epitaxial pattern 220_2).

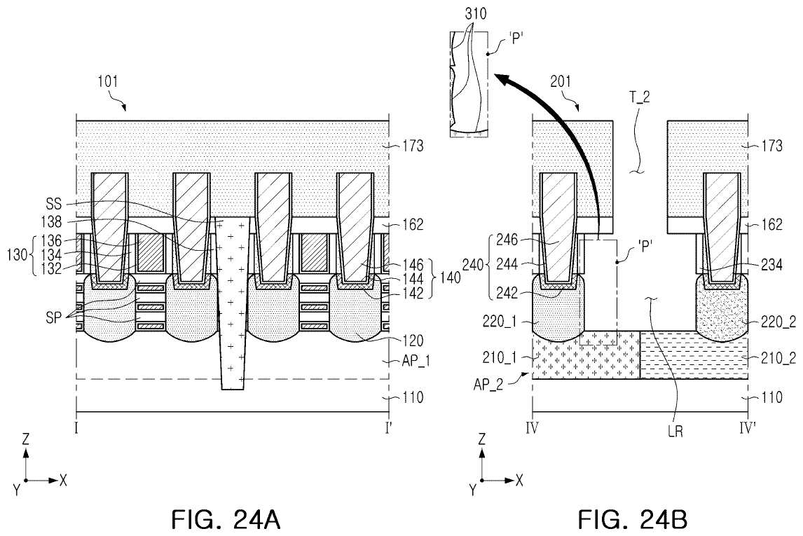

Referring to FIGS. 24A-24B, the silicon patterns SP positioned between the lower gap regions LR on the second active pattern AP_2 may be removed. In this case, a groove portion 310 may be formed in a region P which is an enlarged portion of the external side portion of the spacer layer 234, the first conductivity-type epitaxial pattern 220_1, and the first conductivity-type impurity region 210_1. The groove portion 310 may be formed by removing a portion of the external sidewall of the spacer layer 234, the first conductivity-type epitaxial pattern 220_1, and the first conductivity-type impurity region 210_1 together with the semiconductor patterns SP. The groove portion 310 may also be formed on the external sidewall of the second conductivity-type impurity region 210_2 and the second conductivity-type epitaxial pattern 220_2. The silicon patterns SP may be removed through a dry etching or wet etching process, or the like. When the silicon patterns SP are removed, a portion of the first intermediate insulating layer 162 may also be removed. Accordingly, in some embodiments of the present disclosure, the width in the first direction between an upper portion and a lower portion of the opening of the first intermediate insulating layer 162 may be varied. In the illustrated example embodiment, the groove portion 310 may have an inwardly curved shape, but an example embodiment thereof is not limited thereto, and the size and/or shape of the groove portion 310 may be varied in example embodiments and may have any size and/or shape.

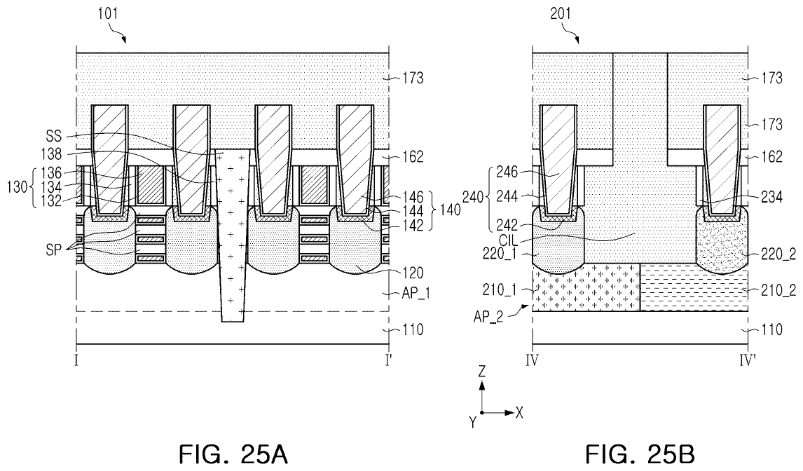

Referring to FIGS. 25A-25B, the removed space may be filled with a central insulating layer CIL. The central insulating layer CIL may fill both the lower gap region LR and the second trench T_2 described with reference to FIGS. 24A-24B. The central insulating layer CIL may be formed of the same material as a material of the first interlayer insulating layer 171 and/or the second interlayer insulating layer 173. In the example embodiment described above, the first conductivity-type impurity region 210_1 and the second conductivity-type impurity region 210_2 of the second device 201 may be in contact with each other in the first direction (e.g., X-direction), thereby forming a p-n bonding structure. Also, the first conductivity-type epitaxial pattern 220_1 and the second conductivity-type epitaxial pattern 220_2 may form a portion of the p-n bonding structure, or may provide an electrical path to the first conductivity-type impurity region 210_1 and the second conductivity-type impurity region 210_2. Also, the central insulating layer CIL may be formed after the second gate structure 230 formed in FIG. 19 is removed from the region between the first conductivity-type epitaxial pattern 220_1 and the second conductivity-type epitaxial pattern 220_2. That is, the second gate structure 230 may be replaced with the central insulating layer CIL. Accordingly, the second device 201 may be implemented as a gate-bounded-diode (GBD) using the gate structure, and may also be implemented as various electronic devices or a semiconductor device including a p-n bonding structure.

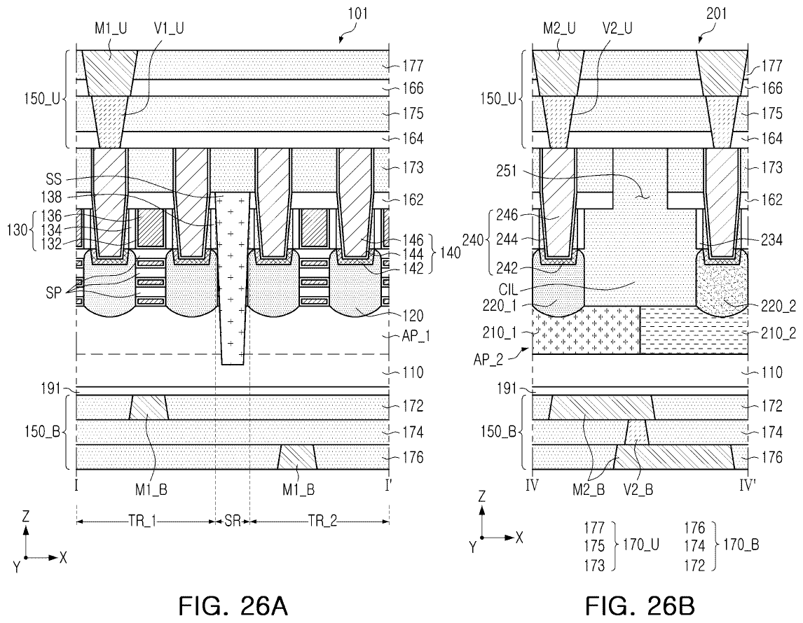

Referring to FIGS. 26A-26B, a planarization process may be performed up to the upper surface of the source/drain contacts 140 and the contact structures 240, and a subsequent MOL and backside process, or the like, may be performed, thereby manufacturing a semiconductor device 10 including the first device 101 and the second device 201 according to FIGS. 2 to 11, or FIGS. 26A-26B. As in the above-described example embodiments, the second device 201 may be a gate-bounded-diode (GBD) manufactured by replacing the gate structure with a central insulating layer. As in the above-described example embodiments, a planarization process may be performed after the MOL structures, such as the first intermediate insulating layer 162, the source/drain contacts 140, and the contact structures 240, are formed, such that the intermediate insulating layers (e.g., the first intermediate insulating layer 162, the second intermediate insulating layer 164, and the third intermediate insulating layer 166) and the interlayer insulating layers (e.g., the second interlayer insulating layer 173, the third interlayer insulating layer 175, and the fourth interlayer insulating layer 177) may be more uniformly applied in the subsequent process. Accordingly, process dispersion may be improved, such that a semiconductor device having improved reliability and electrical properties may be provided.

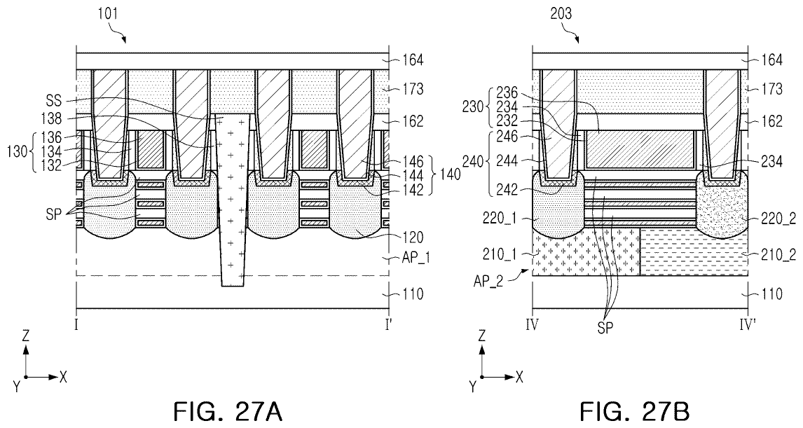

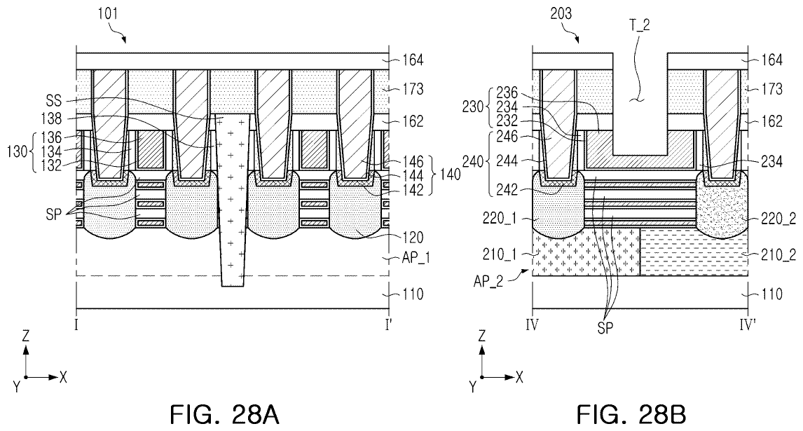

Referring to FIGS. 27A-27B, each process of the method of manufacturing a semiconductor device described with reference to FIGS. 16A to 21B may be performed, a planarization process for the second interlayer insulating layer 173 may be performed, and the second intermediate insulating layer 164 may be formed. Thereafter, referring to FIGS. 28A-28B, the second trench T_2 penetrating the second intermediate insulating layer 164, the second interlayer insulating layer 173, the first intermediate insulating layer 162 and recessed (e.g., penetrating) into at least a portion of the second gate structure 230 may be formed.

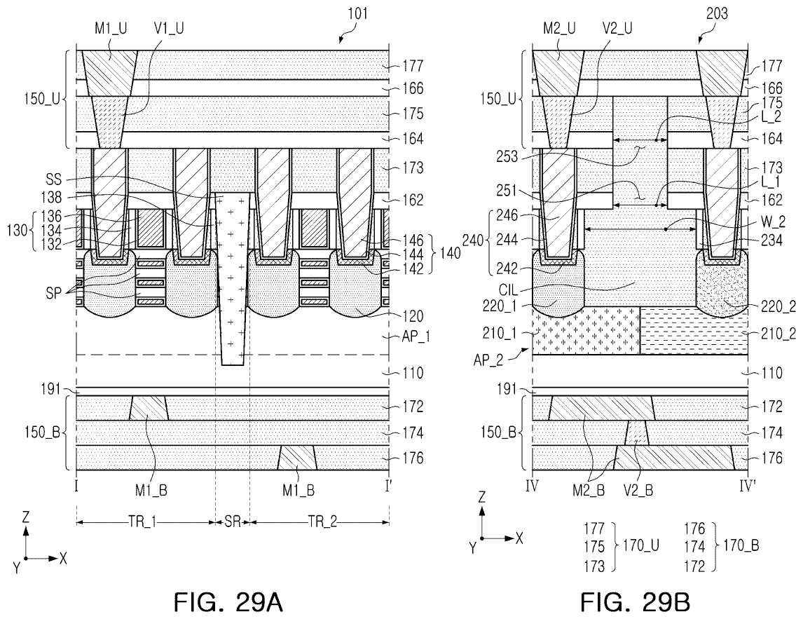

Thereafter, referring to FIGS. 29A-29B, the process described with reference to FIGS. 23A to 25B may be performed, thereby manufacturing the semiconductor device 10 including the second device 203 illustrated in FIG. 13 or FIGS. 29A-29B. In this case, the second opening 253 may be formed together with the second intermediate insulating layer 164. In this case, as the planarization process after filling the central insulating layer CIL is performed after forming the second intermediate insulating layer 164, the intermediate insulating layers (e.g., the first intermediate insulating layer 162, the second intermediate insulating layer 164, and the third intermediate insulating layer 166) and the interlayer insulating layers (e.g., the second interlayer insulating layer 173, the third interlayer insulating layer 175, and the fourth interlayer insulating layer 177) may be applied more uniformly. Accordingly, a semiconductor device having improved reliability and electrical properties may be provided by improving process dispersion.

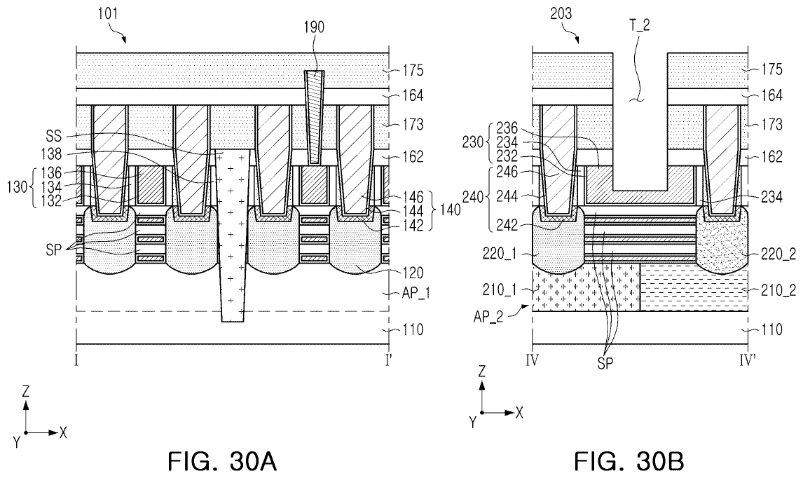

Referring to FIGS. 30A-30B, each process of the method of manufacturing a semiconductor device described with reference to FIGS. 16A to 21B may be performed, a planarization process for the second interlayer insulating layer 173 may be performed, and the second intermediate insulating layer 164 and the third interlayer insulating layer 175 may be formed. Thereafter, a gate contact 190 penetrating the third interlayer insulating layer 175, the second intermediate insulating layer 164, the second interlayer insulating layer 173, and the first intermediate insulating layer 162 and connected to the gate electrode 136 may be formed in the first device 101. Thereafter, a second trench T_2 penetrating the third interlayer insulating layer 175, the second intermediate insulating layer 164, the second interlayer insulating layer 173, and the first intermediate insulating layer 162, and recessed (e.g., penetrating) into at least a portion of the second gate structure 230 may be formed in the second device 203. Thereafter, by performing the process described with reference to FIGS. 23A to 25B, a semiconductor device 10 including the second device 203 according to example embodiments illustrated in FIG. 13 or FIGS. 29A-29B may be manufactured.

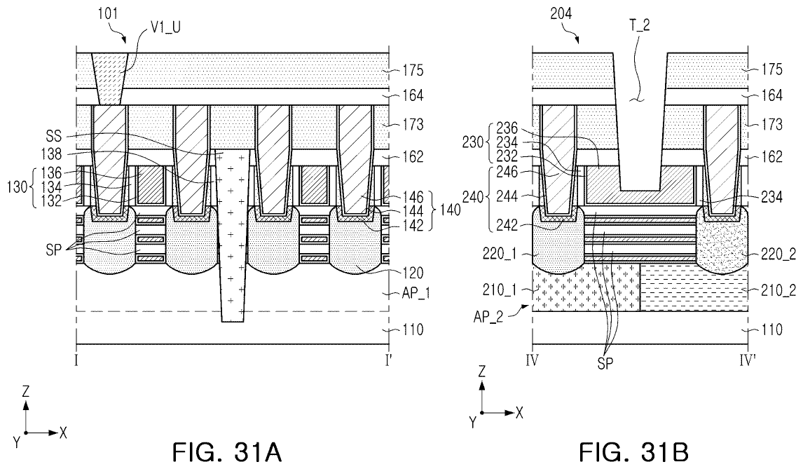

Referring to FIGS. 31A-31B, each process of the method of manufacturing a semiconductor device described with reference to FIGS. 16A to 21B may be performed, a planarization process for the second interlayer insulating layer 173 may be performed, and a second intermediate insulating layer 164 and a third interlayer insulating layer 175 may be formed. Thereafter, a first upper via V1_U penetrating the third interlayer insulating layer 175 and the second intermediate insulating layer 164, and connected to the source/drain contact 140 may be formed in the first device 101. Thereafter, a second trench T_2 penetrating the third interlayer insulating layer 175, the second intermediate insulating layer 164, the second interlayer insulating layer 173, and the first intermediate insulating layer 162 and at least partially recessed (e.g., penetrating) into the second gate structure 230 may be formed in the second device 204. As illustrated, the second trench T_2 may be formed in a tapered shape in which the width in the first direction (e.g., X-direction) decreases toward the substrate 110 in the third direction (e.g., Z-direction). The shape of the second trench T_2 illustrated in FIG. 31 may also be applied to the second trench T_2 according to the example embodiments described with reference to FIGS. 22A to 24B, 28A-28B, 29A-29B, and 32A-32B described below.

When the shape of the second trench T_2 illustrated in FIGS. 31A-31B is adopted in the disclosed example embodiments, the profile of the intermediate insulating layers of the second devices may be formed differently from the illustrated example embodiments. For example, the shapes of the openings (e.g., the first opening 251, the second opening 253, and the third opening 255) disclosed in FIGS. 5, 12, 13, 14, 26A-26B, 29A-29B, or 33A-33B may be different. For example, the widths in the first direction (e.g., X-direction) of the openings (e.g., the first opening 251, the second opening 253, and the third opening 255) of an upper portion may be greater than the widths in the first direction of the openings (e.g., the first opening 251, the second opening 253, and the third opening 255), respectively.

Thereafter, by performing the processes described with reference to FIGS. 23A to 25B, the semiconductor device 10 including the second device 203 according to example embodiments illustrated in FIG. 13 or 29 may be manufactured.

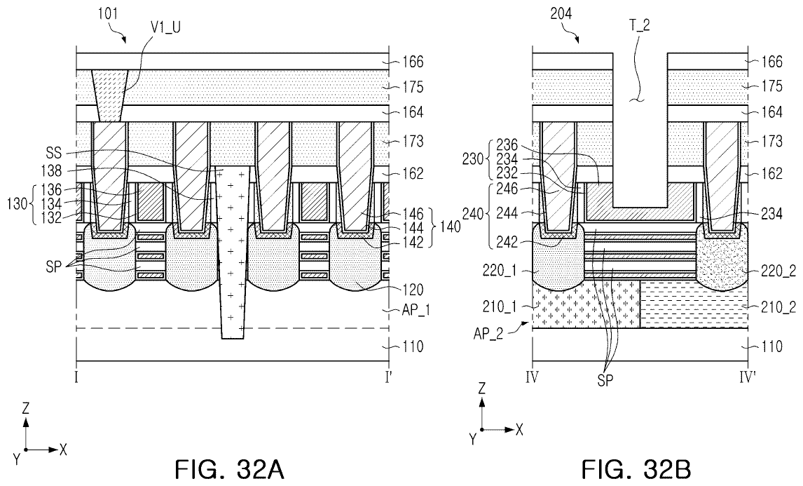

Referring to FIGS. 32A-32B, each process of the method of manufacturing a semiconductor device described with reference to FIGS. 16A to 21B may be performed, a planarization process for a second interlayer insulating layer 173 may be performed, and a second intermediate insulating layer 164 and a third interlayer insulating layer 175 may be formed. Thereafter, a first upper via V1_U penetrating the third interlayer insulating layer 175 and the second intermediate insulating layer 164 and connected to the source/drain contact 140 may be formed in the first device 101. Thereafter, the third intermediate insulating layer 166 may be further formed.

The third intermediate insulating layer 166 may be formed, and a second trench T_2 penetrating the third intermediate insulating layer 166, the third interlayer insulating layer 175, the second intermediate insulating layer 164, the second interlayer insulating layer 173, and the first intermediate insulating layer 162, and recessed (e.g., protrude) into at least a portion of the second gate structure 230 may be formed in the second device 204.

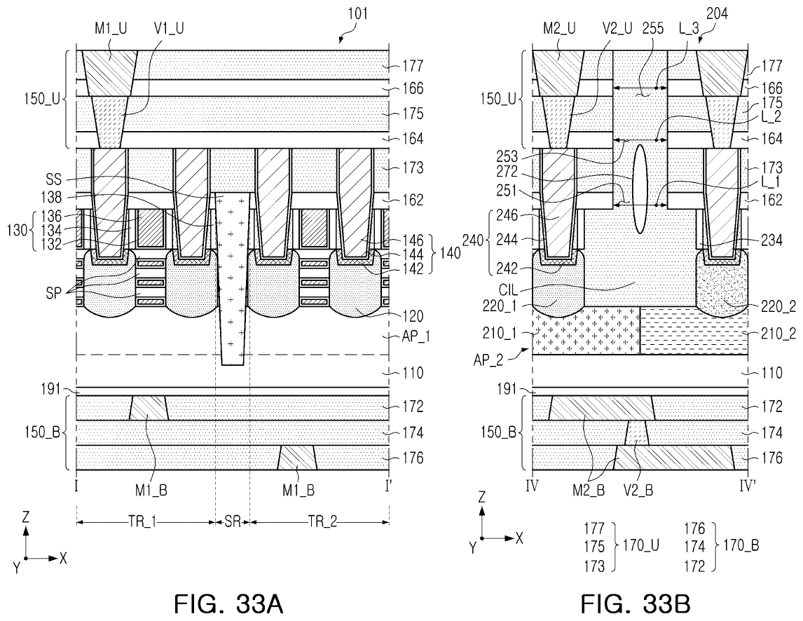

Thereafter, referring to FIGS. 33A-33B, the process described with reference to FIGS. 23A to 25B may be performed, thereby manufacturing a semiconductor device 10 including the second device 204 illustrated in FIG. 14 or FIG. 33A-33B. In this case, a second opening 253 may be formed in a second intermediate insulating layer 164, and a third opening 255 may be formed together in a third intermediate insulating layer 166. Also, a void 272 may be formed together in the central insulating layer CIL. In example embodiments described above, the widths L_1, L_2, and L_3 in the first direction (e.g., X-direction) of the first to third openings (e.g., the first opening 251, the second opening 253, and the third opening 255) may be the same or different from each other. For example, the width L_3 in the first direction of the third opening 255 may be the longest. Specifically, referring to FIGS. 31A-31B and 32A-32B together, to manufacture the second device 204 in FIGS. 33A-33B, a second trench T_2 having a shape similar to the example embodiment illustrated in FIGS. 31A-31B may be formed by the process illustrated in FIGS. 32A-32B. That is, in FIGS. 321-32B, the second trench T_2 may have a side surface slope (e.g., a tapered shape) in which the width in the first direction (e.g., X-direction) decreases toward the substrate 110. In this case, the widths L_1, L_2, and L_3 in the first direction of the first to third openings (e.g., the first opening 251, the second opening 253, and the third opening 255) may be defined as an average value of the widths in the first direction of upper portions of the openings (e.g., the first opening 251, the second opening 253, and the third opening 255) and the width in the first direction of lower portions of the openings (e.g., the first opening 251, the second opening 253, and the third opening 255), respectively. Accordingly, the width L_3 in the first direction of the third opening 255 may be longer than the width L_2 in the first direction of the second opening 253, and the width L_2 in the first direction of the second opening 253 may be longer than the width L_1 in the first direction of the first opening 251.

According to the example embodiments described with reference to FIGS. 32A-32B and 33A-33B, as the planarization process after filling the central insulating layer CIL is performed after the third intermediate insulating layer 166 is formed, the intermediate insulating layers (e.g., the first intermediate insulating layer 162, the second intermediate insulating layer 164, and the third intermediate insulating layer 166) and the interlayer insulating layers (e.g., the second interlayer insulating layer 173, the third interlayer insulating layer 175, and the fourth interlayer insulating layer 177) may be applied more uniformly. Accordingly, process dispersion may be improved such that a semiconductor device having improved reliability and electrical properties may be provided.

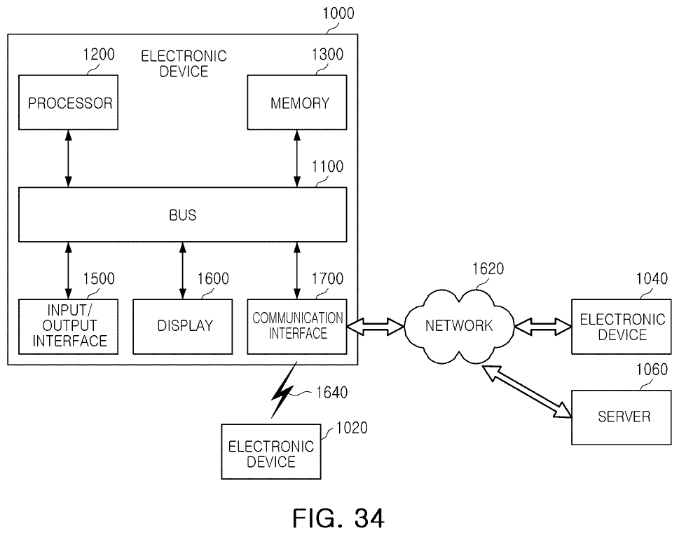

FIG. 34 is a block diagram illustrating an electronic device including a semiconductor device according to some example embodiments. Referring to FIG. 34, an electronic device 1000 may include a bus 1100, a processor 1200, a memory 1300, an input/output interface 1500, a display 1600, and a communication interface 1700. In some example embodiments, in the electronic device 1000, at least one of the elements may not be provided or additional elements may be included. The bus 1100 may include a circuit for interconnecting the elements (e.g., the bus 1100, the processor 1200, the memory 1300, the input/output interface 1500, the display 1600, and the communication interface 1700) and transferring communications (e.g., control messages or data) between the elements. The processor 1200 may include one or more from among a central processing unit, an application processor, and a communication processor (CP). The processor 1200 may execute computation or data processing related to, for example, controlling and/or communicating with at least one other element of the electronic device 1000. The processor 1200 may include at least one semiconductor device 10 according to example embodiments described with reference to FIGS. 1 to 33B.

The memory 1300 may include a volatile and/or nonvolatile memory. The memory 1300 may store, for example, instructions or data related to at least one other element of the electronic device 1000. According to an example embodiment, the memory 1300 may store software and/or programs.

The input/output interface 1500 may transfer, for example, instructions or data input from a user or another external device to other element(s) of the electronic device 1000, or output instructions or data received from other element(s) of the electronic device 1000 to a user or another external device.

The display 1600 may include, for example, a liquid crystal display (LCD), a light emitting diode (LED) display, an organic light emitting diode (OLED) display, a micro electro mechanical systems (MEMS) display, or an electronic paper display. The display 1600 may display, for example, various content (e.g., text, images, videos, icons, and/or symbols) to a user. The display 1600 may include a touch screen and may receive touch, gesture, proximity, or hovering inputs, for example, using an electronic pen or a portion of a body of a user. The communication interface 1700 may establish communications between, for example, the electronic device 1000 and external devices (e.g., a first external electronic device 1020, a second external electronic device 1040, or a server 1060). For example, the communication interface 1700 may be connected to the network 1620 through wireless or wired communication and may communicate with an external device (e.g., the second external electronic device 1040 or the server 1060).

The wireless communication may include cellular communication using, for example, at least one of LTE, LTE Advance (LTE-A), code division multiple access (CDMA), wideband CDMA (WCDMA), universal mobile telecommunications system (UMTS), wireless broadband (WiBro), or global system for mobile communications (GSM). According to an example embodiment, the wireless communication may include, for example, at least one from among wireless fidelity (WiFi), Bluetooth, Bluetooth low energy (BLE), Zigbee, near field communication (NFC), magnetic secure transmission, radio frequency (RF), and a body area network (BAN). According to an example embodiment, the wireless communication may include global navigation satellite system (GNSS). The GNSS may be, for example, global positioning system (GPS), Glonass (global navigation satellite system), Beidou navigation satellite system (hereinafter “Beidou”), or Galileo, the European global satellite-based navigation system. Hereinafter, in example embodiments, “GPS” may be used interchangeably with “GNSS.” The wired communication may include at least one from among, for example, universal serial bus (USB), high definition multimedia interface (HDMI), recommended standard-232 (RS-232), power line communication, and plain old telephone service (POTS). The network 1620 may include at least one from among a telecommunications network, for example, a computer network (e.g., a local area network (LAN) or a wide area network (WAN)), the Internet, and a telephone network.

The first external electronic device 1020 and the second external electronic device 1040 may be the same or different types of devices as the electronic device 1000. According to various example embodiments, the entirety or a portion of operations executed by the electronic device 1000 may be executed by the other one or a plurality of electronic devices (e.g., the first external electronic device 1020, the second external electronic device 1040, or the server 1060). According to an example embodiment, when the electronic device 1000 performs a function or service automatically or upon request, the electronic device 1000 may, instead of executing the function or service, request at least a portion of the function associated therewith from another device (e.g., the first external electronic device 1020, the second external electronic device 1040, or the server 1060). The other electronic device (e.g., the first external electronic device 1020, the second external electronic device 1040, or the server 1060) may execute the requested function or additional function and may transfer the result to the electronic device 1000. The electronic device 1000 may process the received result as is or and may additionally provide the requested function or service. To this end, for example, cloud computing, distributed computing, or client-server computing techniques may be used.

According to the aforementioned example embodiments, by performing a planarization process after forming a middle of line (MOL) structure such as a contact structure, an intermediate insulating layer and an interlayer insulating layer may be uniformly applied. Accordingly, process dispersion may be improved, and a semiconductor device having improved reliability and electrical properties may be provided.

According to some example embodiments of the present disclosure, a method of manufacturing a semiconductor device may include: alternately stacking sacrificial layers and semiconductor patterns extending in the first direction on a substrate; forming an active structure including a first active pattern and a second active pattern; forming a first sacrificial gate structure on the first active pattern; forming a second sacrificial gate structure having a width in the first direction different from a width of the first sacrificial gate structure on the second active pattern; forming source/drain patterns on the first active pattern; forming conductivity epitaxial patterns on the second active pattern; forming a first gate structure on the first active pattern; forming a second gate structure on the second active pattern; forming a first intermediate insulating layer on the first and second active patterns; forming an isolation structure penetrating the first active pattern; forming source/drain contacts on the first active pattern; forming contact structures on the conductive epitaxial patterns; removing a portion of the second gate structure and semiconductor patterns on the second active pattern; and forming a central insulating layer.

The forming the first gate structure may further include forming a gate electrode extending in a second direction intersecting the first direction, the gate electrode intersecting and at least partially surrounding the semiconductor patterns, and the forming the second gate structure may further include forming a sacrificial gate electrode intersecting the semiconductor patterns, extending in the second direction and at least partially surrounding the semiconductor patterns.

The removing the portion of the second gate structure may further include removing the sacrificial gate electrode.

The forming the central insulating layer may further include forming the central insulating layer to be disposed between and in contact with adjacent ones of the spacer layers.

The method may further include forming a first interlayer insulating layer on the source/drain patterns and the first and second conductivity-type epitaxial patterns.

The method may further include forming a second interlayer insulating layer on the first intermediate insulating layer.

The method may further include forming a trench to penetrate the first intermediate insulating layer and the second interlayer insulating layer and to remove a portion of the second gate structure.

The forming the trench may include forming the trench to penetrate the first intermediate insulating layer and the second interlayer insulating layer, and to protrude into at least a portion of the second gate structure.

The forming the central insulating layer may further include forming the central insulating layer to fill the trench.

The forming source/drain contacts and contact structures may include forming source/drain contacts and contact structures such that upper surfaces of the source/drain contacts and the contact structures are positioned on a level higher than a level of an upper surface of the isolation structure.

The forming source/drain contacts and contact structures may include forming a second intermediate insulating layer on the source/drain contacts and the contact structures.

While non-limiting example embodiments of the present disclosure have been described above with reference to the accompanying drawings, it will be apparent to those skilled in the art that modifications and variations could be made without departing from the spirit and scope of the present disclosure.

What is claimed is:

1. A semiconductor device, comprising:
a substrate;
an active pattern extending in a first direction on a first surface of the substrate, the active pattern comprising at least one conductivity-type impurity region;
a first conductivity-type epitaxial pattern on the at least one conductivity-type impurity region;
a second conductivity-type epitaxial pattern on the at least one conductivity-type impurity region, and spaced apart from the first conductivity-type epitaxial pattern in the first direction;
a first interlayer insulating layer on the first surface of the substrate, the first conductivity-type epitaxial pattern, and the second conductivity-type epitaxial pattern;
a first intermediate insulating layer on the first interlayer insulating layer, the first intermediate insulating layer including a first opening extending in a second direction, intersecting the first direction;
a central insulating layer between the first conductivity-type epitaxial pattern and the second conductivity-type epitaxial pattern, wherein the central insulating layer extends in the second direction and is in the first opening; and
contact structures penetrating through the first interlayer insulating layer and the first intermediate insulating layer, and respectively in contact with the first conductivity-type epitaxial pattern and the second conductivity-type epitaxial pattern.

2. The semiconductor device of claim 1, wherein the first opening is on a region, the region being between the first conductivity-type epitaxial pattern and the second conductivity-type epitaxial pattern in the first direction.

3. The semiconductor device of claim 1, further comprising:
spacer layers on a side surface of the first interlayer insulating layer in the first direction, the spacer layers extending in the second direction,
wherein the central insulating layer is between and in contact with adjacent ones of the spacer layers.

4. The semiconductor device of claim 3, wherein a width in the first direction of a portion of the central insulating layer between the spacer layers is longer than a width in the first direction of the first opening.

5. The semiconductor device of claim 1, further comprising:
a second interlayer insulating layer on the first intermediate insulating layer,
wherein a material of the central insulating layer is the same as a material of the second interlayer insulating layer.

6. The semiconductor device of claim 5, wherein the contact structures penetrate the second interlayer insulating layer and are in contact with the first conductivity-type epitaxial pattern and the second conductivity-type epitaxial pattern, respectively.

7. The semiconductor device of claim 5, further comprising:
a second intermediate insulating layer on the second interlayer insulating layer, the second intermediate insulating layer including a second opening extending in the second direction,
wherein the central insulating layer is in the second opening.

8. The semiconductor device of claim 1, further comprising:
an upper interconnection structure comprising an upper via and an upper metal line, the upper via and the upper metal line being on at least one of the contact structures; and
a lower interconnection structure comprising a lower via and a lower metal line, the lower via and the lower metal line being on a second surface of the substrate, opposite to the first surface.

9. The semiconductor device of claim 8, further comprising:
a through-buried structure penetrating the substrate, the first interlayer insulating layer, and the first intermediate insulating layer, and in contact with the upper interconnection structure and the lower interconnection structure.

10. The semiconductor device of claim 1,
wherein the at least one conductivity-type impurity region comprises a first conductivity-type impurity region and a second conductivity-type impurity region in contact with each other in the first direction, and
wherein the first opening overlaps, in a third direction intersecting the first direction and the second direction, with an interface between the first conductivity-type impurity region and the second conductivity-type impurity region.

11. The semiconductor device of claim 1, further comprising:
a void in the central insulating layer,
wherein the void overlaps with the first opening in the first direction.

12. A semiconductor device, comprising:
a substrate;
a first device on a first surface of the substrate; and
a second device on the first surface of the substrate and spaced apart from the first device,
wherein the first device comprises:
a first active pattern extending in a first direction on the first surface of the substrate;
semiconductor patterns on the first active pattern, the semiconductor patterns spaced apart from each other in a third direction crossing the first surface of the substrate;
a gate electrode extending in a second direction intersecting the first direction and the third direction, the gate electrode intersecting and at least partially surrounding the semiconductor patterns;
source/drain patterns in contact with the semiconductor patterns on at least one side of the gate electrode;
an isolation structure extending in the second direction, the isolation structure being between adjacent ones of the source/drain patterns; and
source/drain contacts in contact with the source/drain patterns,
wherein the second device comprises:
a second active pattern comprising a first conductivity-type impurity region and a second conductivity-type impurity region, the first conductivity-type impurity region and the second conductivity-type impurity region extending in the first direction on the first surface of the substrate, and contacting each other in the first direction;
a first conductivity-type epitaxial pattern on the first conductivity-type impurity region;
a second conductivity-type epitaxial pattern on the second conductivity-type impurity region, the second conductivity-type epitaxial pattern spaced apart from the first conductivity-type epitaxial pattern in the first direction;
an interlayer insulating layer on the first surface of the substrate, the first conductivity-type epitaxial pattern, and the second conductivity-type epitaxial pattern;
an intermediate insulating layer including an opening extending in the second direction, the intermediate insulating layer being on the interlayer insulating layer; and
a central insulating layer between the first conductivity-type epitaxial pattern and the second conductivity-type epitaxial pattern, wherein the central insulating layer extends in the second direction and is in the opening, and
wherein the opening overlaps, in the third direction, with an interface between the first conductivity-type impurity region and the second conductivity-type impurity region.

13. The semiconductor device of claim 12, further comprising:
contact structures penetrating through the interlayer insulating layer and the intermediate insulating layer and respectively in contact with the first conductivity-type epitaxial pattern and the second conductivity-type epitaxial pattern,
wherein an upper surface of the isolation structure is at a level lower than a level of an upper surface of the contact structures in the third direction.

14. The semiconductor device of claim 13,
wherein each of the contact structures comprises a conductive material, a conductive barrier on an upper surface and a side surface of the conductive material, and a metal silicide film in contact with at least one from among the first conductivity-type epitaxial pattern and the second conductivity-type epitaxial pattern, and
wherein the conductive barrier is between the metal silicide film and the conductive material.

15. The semiconductor device of claim 12, wherein a material of the first conductivity-type epitaxial pattern is the same as a material of the source/drain patterns.

16. The semiconductor device of claim 12, wherein the central insulating layer entirely overlaps with the gate electrode in the first direction and the second direction.

17. The semiconductor device of claim 12, further comprising:
gate electrode spacer layers on opposite sides of the gate electrode in the first direction; and
spacer layers on a side surface of the interlayer insulating layer in the first direction, the spacer layers extending in the second direction,
wherein the central insulating layer is between and in contact with adjacent ones of the spacer layers.

18. The semiconductor device of claim 17, wherein a width in the first direction of a portion of the gate electrode between the gate electrode spacer layers is smaller than a width in the first direction of a portion of the central insulating layer between the spacer layers.

19. The semiconductor device of claim 12, further comprising:
a void in the central insulating layer,
wherein the void overlaps with the opening in the first direction.

20. A semiconductor device, comprising:
a substrate;
an active pattern extending in a first direction on a first surface of the substrate, the active pattern comprising at least one conductivity-type impurity region;
a first conductivity-type epitaxial pattern on the at least one conductivity-type impurity region;
a second conductivity-type epitaxial pattern on the at least one conductivity-type impurity region, and spaced apart from the first conductivity-type epitaxial pattern in the first direction;
an interlayer insulating layer on the first surface of the substrate, the first conductivity-type epitaxial pattern, and the second conductivity-type epitaxial pattern;
an intermediate insulating layer including an opening extending in a second direction, intersecting the first direction, the intermediate insulating layer being on the interlayer insulating layer;
a central insulating layer between the first conductivity-type epitaxial pattern and the second conductivity-type epitaxial pattern, wherein the central insulating layer extends in the second direction and is in the opening;
contact structures penetrating through the interlayer insulating layer and the intermediate insulating layer and respectively in contact with the first conductivity-type epitaxial pattern and the second conductivity-type epitaxial pattern;
an upper interconnection structure comprising an upper via and an upper metal line, the upper via and the upper metal line being on at least one of the contact structures; and
a lower interconnection structure comprising a lower via and a lower metal line, the lower via and the lower metal line being on a second surface of the substrate, opposite to the first surface,
wherein the at least one conductivity-type impurity region comprises a first conductivity-type impurity region and a second conductivity-type impurity region in contact with each other in the first direction, and
wherein the opening overlaps, in a third direction intersecting the first direction and the second direction, with an interface between the first conductivity-type impurity region and the second conductivity-type impurity region.
